(19) United States
(12) Patent Application Publication
(10) Pub. No.: US 2025/0098141 A1
(43) Pub. Date: Mar. 20, 2025

(54) SEMICONDUCTOR MEMORY DEVICE

(71) Applicant: Kioxia Corporation, Tokyo (JP)

(72) Inventor: Mutsumi OKAJIMA, Yokkaichi Mie (JP)

(73) Assignee: Kioxia Corporation, Tokyo (JP)

(21) Appl. No.: 18/595,199

(22) Filed: Mar. 4, 2024

(30) Foreign Application Priority Data
Sep. 20, 2023 (JP) 2023-153972

(51) Int. Cl. H10B 12/00; H01L 23/00; H01L 25/065; H01L 25/18; H10B 80/00

(52) U.S. Cl. CPC H10B 12/30; H01L 24/08; H01L 25/0657; H01L 25/18; H10B 12/03; H10B 12/05; H10B 80/00; H01L 2224/08145; H01L 2924/1431; H01L 2924/1436

(57) ABSTRACT

A semiconductor memory device includes: a substrate; a first wiring; a first semiconductor layer disposed between the substrate and the first wiring; second semiconductor layers disposed between the first semiconductor layer and the first wiring; a first via-wiring connected to the first and the second semiconductor layers; a first memory portion connected to the first semiconductor layer; a first gate electrode opposed to the first semiconductor layer; a second wiring connected to the first gate electrode; connection electrodes connected to the second semiconductor layers; second gate electrodes opposed to the second semiconductor layers; third wirings disposed between the second and the first wiring and connected to the second gate electrodes; a fourth wiring connected to the first memory portion; a fifth wiring connected to the connection electrodes in common; and an insulating layer disposed between the fourth wiring and the fifth wiring.

### CROSS-REFERENCE TO RELATED APPLICATIONS

This application is based upon and claims the benefit of Japanese Patent Application No. 2023-153972, filed on Sep. 20, 2023, the entire contents of which are incorporated herein by reference.

### BACKGROUND

### Field

Embodiments described herein relate generally to a semiconductor memory device.

### Description of the Related Art

In accordance with an increasing high integration of a semiconductor memory device, an examination for converting the semiconductor memory device into a three-dimensional form has been in progress.

### BRIEF DESCRIPTION OF THE DRAWINGS

FIG. 1 is a schematic exploded perspective view illustrating an exemplary configuration of a semiconductor memory device according to a first embodiment;

FIG. 2 is a schematic circuit diagram illustrating a configuration of the semiconductor memory device;

FIG. 3 is a schematic perspective view illustrating a configuration of a part of the semiconductor memory device;

FIG. 4 is a schematic XY cross-sectional view illustrating a configuration of a part a memory layer ML;

FIG. 5 is a schematic XY cross-sectional view illustrating a configuration of a part of a transistor layer TL;

FIG. 6 is a schematic XY cross-sectional view illustrating a configuration of a part of the memory layer ML;

FIG. 7 is a cross-sectional view of a structure illustrated in FIG. 6 taken along line C-C′ and viewed along an arrow direction;

FIG. 8 is a schematic XY cross-sectional view illustrating a configuration of a part of the transistor layer TL;

FIG. 9 is a cross-sectional view of a structure illustrated in FIG. 8 taken along line D-D′ and viewed in an arrow direction;

FIG. 10 is a schematic cross-sectional view illustrating the configuration of the semiconductor memory device according to the first embodiment;

FIG. 11 is a schematic cross-sectional view illustrating the configuration of the semiconductor memory device;

FIG. 12 is a schematic cross-sectional view for describing a manufacturing method of the semiconductor memory device;

FIG. 13 is a schematic cross-sectional view for describing the manufacturing method;

FIG. 14 is a schematic cross-sectional view for describing the manufacturing method;

FIG. 15 is a schematic cross-sectional view for describing the manufacturing method;

FIG. 16 is a schematic cross-sectional view for describing the manufacturing method;

FIG. 17 is a schematic cross-sectional view for describing the manufacturing method;

FIG. 18 is a schematic cross-sectional view for describing the manufacturing method;

FIG. 19 is a schematic cross-sectional view for describing the manufacturing method;

FIG. 20 is a schematic cross-sectional view for describing the manufacturing method;

FIG. 21 is a schematic cross-sectional view for describing the manufacturing method;

FIG. 22 is a schematic cross-sectional view for describing the manufacturing method;

FIG. 23 is a schematic cross-sectional view for describing the manufacturing method;

FIG. 24 is a schematic cross-sectional view for describing the manufacturing method;

FIG. 25 is a schematic cross-sectional view for describing the manufacturing method;

FIG. 26 is a schematic cross-sectional view for describing the manufacturing method;

FIG. 27 is a schematic cross-sectional view for describing the manufacturing method;

FIG. 28 is a schematic cross-sectional view for describing the manufacturing method;

FIG. 29 is a schematic cross-sectional view for describing the manufacturing method;

FIG. 30 is a schematic cross-sectional view for describing the manufacturing method;

FIG. 31 is a schematic cross-sectional view for describing the manufacturing method;

FIG. 32 is a schematic cross-sectional view for describing the manufacturing method;

FIG. 33 is a schematic cross-sectional view for describing the manufacturing method;

FIG. 34 is a schematic cross-sectional view for describing the manufacturing method;

FIG. 35 is a schematic cross-sectional view for describing the manufacturing method;

FIG. 36 is a schematic cross-sectional view for describing the manufacturing method;

FIG. 37 is a schematic cross-sectional view for describing the manufacturing method;

FIG. 38 is a schematic cross-sectional view for describing the manufacturing method;

FIG. 39 is a schematic cross-sectional view for describing the manufacturing method;

FIG. 40 is a schematic cross-sectional view for describing the manufacturing method;

FIG. 41 is a schematic cross-sectional view for describing the manufacturing method;

FIG. 42 is a schematic cross-sectional view for describing the manufacturing method;

FIG. 43 is a schematic cross-sectional view for describing the manufacturing method;

FIG. 44 is a schematic cross-sectional view for describing the manufacturing method;

FIG. 45 is a schematic cross-sectional view for describing the manufacturing method;

FIG. 46 is a schematic cross-sectional view for describing the manufacturing method;

FIG. 47 is a schematic cross-sectional view for describing the manufacturing method;

FIG. 48 is a schematic cross-sectional view for describing the manufacturing method;

FIG. 49 is a schematic cross-sectional view for describing the manufacturing method;

FIG. 50 is a schematic cross-sectional view for describing the manufacturing method;

FIG. 51 is a schematic cross-sectional view for describing the manufacturing method;

FIG. 52 is a schematic cross-sectional view illustrating a configuration of a part of a semiconductor memory device according to a second embodiment;

FIG. 53 is a schematic cross-sectional view illustrating a configuration of a part of the semiconductor memory device;

FIG. 54 is a schematic cross-sectional view illustrating a configuration of a part of a semiconductor memory device according to a third embodiment;

FIG. 55 is a schematic cross-sectional view illustrating a configuration of a part of the semiconductor memory device;

FIG. 56 is a schematic cross-sectional view illustrating a configuration of a part of the semiconductor memory device;

FIG. 57 is a schematic cross-sectional view illustrating a configuration of a part of a semiconductor memory device according to a fourth embodiment;

FIG. 58 is a schematic cross-sectional view illustrating a configuration of a part of the semiconductor memory device;

FIG. 59 is a schematic cross-sectional view illustrating a configuration of a part of the semiconductor memory device;

FIG. 60 is a schematic cross-sectional view illustrating a configuration of a part of a semiconductor memory device according to a fifth embodiment;

FIG. 61 is a schematic cross-sectional view illustrating a configuration of a part of the semiconductor memory device;

FIG. 62 is a schematic cross-sectional view illustrating a configuration of a part of the semiconductor memory device; and

FIG. 63 is a schematic cross-sectional view illustrating a configuration of a part of a semiconductor memory device according to another embodiment.

### DETAILED DESCRIPTION

A semiconductor memory device according to one embodiment comprises: a substrate; a first wiring disposed on one side in a first direction intersecting with a surface of the substrate with respect to the substrate and extending in a second direction intersecting with the first direction; a first semiconductor layer disposed between the substrate and the first wiring; a plurality of second semiconductor layers disposed between the first semiconductor layer and the first wiring and stacked in the first direction; a first via-wiring extending in the first direction and electrically connected to the first semiconductor layer and the plurality of second semiconductor layers; a first memory portion electrically connected to the first semiconductor layer; a first gate electrode opposed to the first semiconductor layer; a second wiring extending in a third direction intersecting with the first direction and the second direction and electrically connected to the first gate electrode; a plurality of connection electrodes disposed between the first memory portion and the first wiring, stacked in the first direction, and electrically connected to the respective plurality of second semiconductor layers; a plurality of second gate electrodes disposed between the first gate electrode and the first wiring, stacked in the first direction, and opposed to the respective plurality of second semiconductor layers; a plurality of third wirings disposed between the second wiring and the first wiring, stacked in the first direction, extending in the third direction, and electrically connected to the respective plurality of second gate electrodes; a fourth wiring extending in the first direction and electrically connected to the first memory portion; a fifth wiring extending in the first direction and electrically connected to the plurality of connection electrodes in common; and an insulating layer disposed between the fourth wiring and the fifth wiring.

Next, the semiconductor memory devices according to embodiments are described in detail with reference to the drawings. The following embodiments are only examples, and not described for the purpose of limiting the present invention. The following drawings are schematic, and for convenience of description, a part of a configuration and the like is sometimes omitted. Parts common in a plurality of embodiments are attached by same reference numerals and their descriptions may be omitted.

In this specification, when referring to a “semiconductor memory device”, it may mean a memory die and may mean a memory system including a controller die, such as a memory chip, a memory card, and a Solid State Drive (SSD). Further, it may mean a configuration including a host computer, such as a smartphone, a tablet terminal, and a personal computer.

In this specification, when it is referred that a first configuration “is electrically connected” to a second configuration, the first configuration may be directly connected to the second configuration, and the first configuration may be connected to the second configuration via a wiring, a semiconductor member, a transistor, or the like. For example, when three transistors are connected in series, even when the second transistor is in an OFF state, the first transistor is “electrically connected” to the third transistor.

In this specification, when it is referred that the first configuration “is electrically connected between” the second configuration and a third configuration, it may mean that the first configuration, the second configuration, and the third configuration are connected in series and the second configuration is electrically connected to the third configuration via the first configuration.

In this specification, when it is referred that a circuit or the like “electrically conducts” two wirings or the like, it may mean, for example, that this circuit or the like includes a transistor or the like, this transistor or the like is disposed in a current path between the two wirings, and this transistor or the like is turned ON.

In this specification, a direction parallel to an upper surface of a substrate is referred to as an X-direction, a direction parallel to the upper surface of the substrate and perpendicular to the X-direction is referred to as a Y-direction, and a direction perpendicular to the upper surface of the substrate is referred to as a Z-direction.

In this specification, a direction intersecting with a surface of the substrate is referred to as a first direction in some cases. A direction along a predetermined plane intersecting with the first direction may be referred to as a second direction, and a direction along the plane and intersecting with the second direction may be referred to as a third direction. The stacking direction may correspond to the Z-direction and need not correspond to the Z-direction. The second direction and the third direction may each correspond to any of the X-direction or the Y-direction and need not each correspond to any of the X-direction or the Y-direction.

In this specification, when it is referred that a “center position” of a certain configuration, for example, it may mean a position of a center of a circumscribed circle of this configuration or it may mean a center of gravity on an image of this configuration.

### First Embodiment

### [Structure of Memory Die MD]

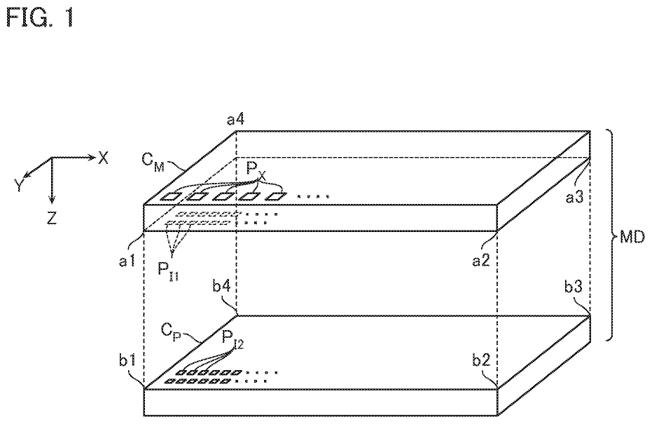

FIG. 1 is a schematic exploded perspective view illustrating an exemplary configuration of a semiconductor memory device according to the first embodiment. As illustrated in FIG. 1, the memory die MD includes a chip C_{M} and a chip C_{P}. The chip C_{M} includes a memory cell array MCA. The chip C_{P} includes a peripheral circuit or the like connected to the memory cell array MCA.

On one surface of the chip C_{M}, a plurality of external pad electrodes P_{X} are disposed. On the other surface of the chip C_{M}, a plurality of first bonding electrodes P_{I1} are disposed. On one surface of the chip C_{P}, a plurality of second bonding electrodes P_{I2} are disposed. Hereinafter, in the chip C_{M}, a surface on which the plurality of first bonding electrodes P_{I1} are disposed is referred to as a front surface, and a surface on which the plurality of external pad electrodes P_{X} are disposed is referred to as a back surface. In the chip C_{P}, a surface on which the plurality of second bonding electrodes P_{I2} are disposed is referred to as a front surface, and a surface on the opposite side of the front surface is referred to as a back surface.

The chip C_{M} and the chip C_{P} are disposed such that the front surface of the chip C_{M} is opposed to the front surface of the chip C_{P}. The plurality of first bonding electrodes P_{I1} are disposed corresponding to the respective plurality of second bonding electrodes P_{I2}, and disposed at positions allowing bonding to the plurality of second bonding electrodes P_{I2}. The first bonding electrode P_{I1} and the second bonding electrode P_{I2} function as bonding electrodes that bond the chip C_{M} and the chip C_{P} together and electrically connect the chip C_{M} and the chip C_{P}.

In the example of FIG. 1, corner portions a1, a2, a3, a4 of the chip C_{M} correspond to corner portions b1, b2, b3, b4 of the chip C_{P}, respectively.

### [Circuit Configuration]

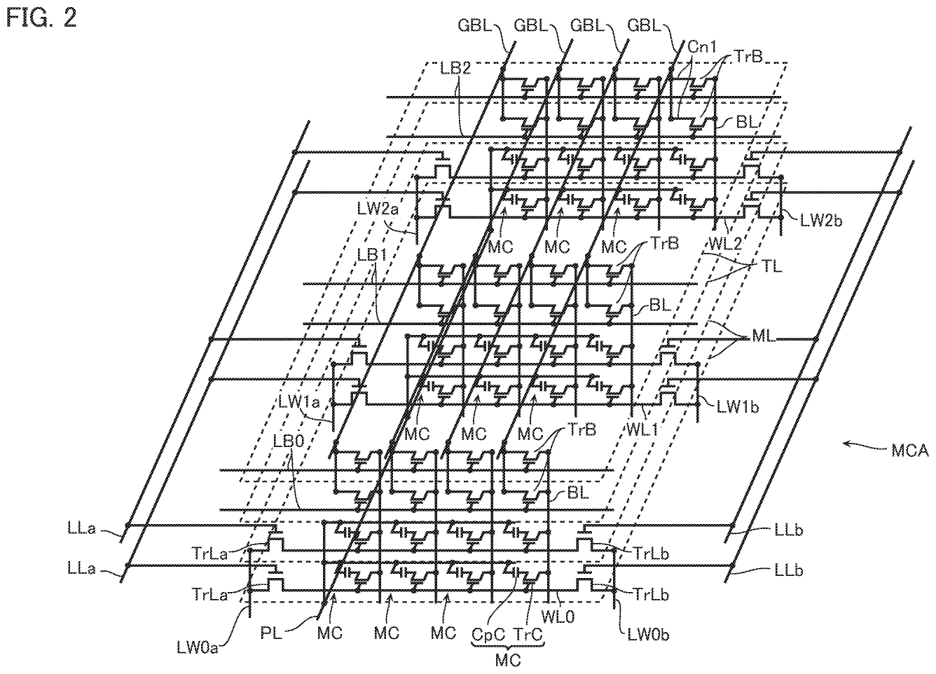

FIG. 2 is a schematic circuit diagram illustrating a configuration of the semiconductor memory device according to the first embodiment. The memory cell array MCA includes a plurality of memory layers ML, a plurality of transistor layers TL, a plurality of bit lines BL connected to these plurality of memory layers ML and plurality of transistor layers TL, a plurality of global bit lines GBL electrically connected to the plurality of bit lines BL via the plurality of transistor layers TL, and a plate line PL connected to the plurality of memory layers ML.

The memory layers ML each include a plurality of word lines WL0 to WL2 (hereinafter referred to as “word lines WL” in some cases) and a plurality of memory cells MC connected to these plurality of word lines WL0 to WL2. The memory cells MC each include a transistor TrC and a capacitor CPC. One electrode of the transistor TrC is connected to the bit line BL. The other electrode of the transistor TrC is connected to the capacitor CPC. Note that one and the other electrode of the transistor TrC function as a source electrode or a drain electrode according to a voltage applied to the transistor TrC. A gate electrode of the transistor TrC is connected to any of the word lines WL0 to WL2. One electrode of the capacitor CPC is connected to the other electrode of the transistor TrC. The other electrode of the capacitor CPC is connected to the plate line PL.

Note that each bit line BL is connected to the plurality of memory cells MC corresponding to the plurality of memory layers ML.

The memory layers ML each include a plurality of transistors TrLa, TrLb (hereinafter referred to as “transistors TrL” in some cases) disposed corresponding to the plurality of word lines WL0 to WL2. One electrode of the transistor TrL is connected to any of the word lines WL0 to WL2. Other electrodes of the respective transistors TrL are connected to word line select lines LW0a, LW0b, LW1a, LW1b, LW2a, LW2b (hereinafter referred to as “word line select lines LW” in some cases). Note that one and the other electrode of the transistor TrL functions as a source electrode or a drain electrode according to a voltage applied to the transistor TrL. Respective gate electrodes of the transistors TrL are connected to layer select lines LLa, LLb (hereinafter referred to as “layer select lines LL” in some cases).

Note that the word line select line LW is connected to the plurality of transistors TrL corresponding to the plurality of memory layers ML. The layer select lines LLa are each connected to all the transistors TrLa corresponding to the plurality of memory layers ML in common. Similarly, the layer select lines LLb are each connected to all the transistors TrLb corresponding to the plurality of memory layers ML in common.

The transistor layer TL includes a plurality of bit line select lines LB0 to LB2 (hereinafter referred to as “bit line select lines LB” in some cases) and a plurality of transistors TrB connected to the plurality of bit line select lines LB0 to LB2. One electrode of the transistor TrB is connected to the global bit line GBL via an electrode Cn1. The other electrode of the transistor TrB is connected to the bit line BL. Note that one and the other electrode of the transistor TrB functions as a source electrode or a drain electrode according to a voltage applied to the transistor TrB. A gate electrode of the transistor TrB is connected to any of the bit line select lines LB0 to LB2.

Note that among the plurality of transistors TrB, the other electrodes of the transistors TrB having one electrode connected to the same bit line BL are each connected to the same global bit line GBL via the electrode Cn1. These plurality of transistors TrB are connected in parallel between the bit line BL and the global bit line GBL.

The plurality of bit line select lines LB0 to LB2 are, for example, connected to a driving circuit or the like disposed on the chip C_{P} via the respective first bonding electrodes P_{I1} and second bonding electrodes P_{I2} (FIG. 1).

### [Structure of Chip C_{P}]

The chip C_{P} (FIG. 1) includes, for example, a control circuit for controlling the memory cell array MCA and the driving circuit. For example, the control circuit includes a sense amplifier circuit. The sense amplifier circuit is electrically connected to the bit line BL via the global bit line GBL. In a read operation, the sense amplifier circuit detects a variation in a voltage or a current of the bit line BL to allow reading data stored in the selected memory cell MC.

### [Structure of Chip C_{M}]

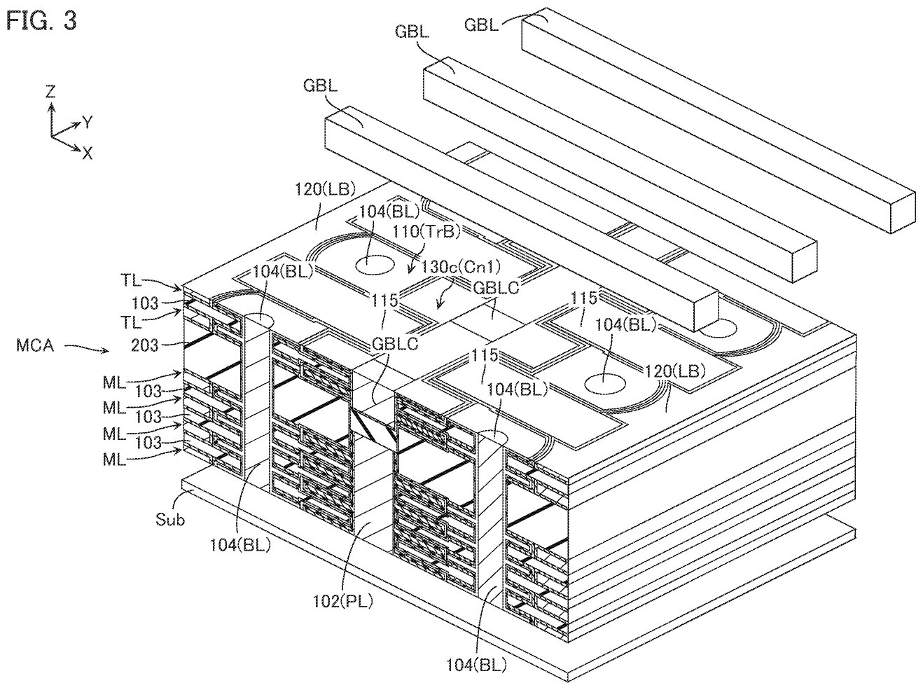

FIG. 3 is a schematic perspective view illustrating a configuration of a part of the semiconductor memory device according to the embodiment. FIG. 3 illustrates a structure of a part of the memory cell array MCA disposed on the chip C_{M}.

Note that, in the following description, expressions, such as “above” and “below”, are based on the global bit line GBL. For example, a direction away from the global bit line GBL along the Z-direction is referred to as below and a direction approaching the global bit line GBL along the Z-direction is referred to as above. When it is referred to as an upper surface and an upper end in a certain configuration, they mean a surface and an end portion at the global bit line GBL side of this configuration, and when it is referred to as a lower surface and a lower end, they mean a surface and an end portion on an opposite side of the global bit line GBL of this configuration. Additionally, a surface intersecting with the X-direction or the Y-direction is referred to as a side surface or the like.

The memory cell array MCA, for example, is disposed between the global bit lines GBL and a substrate Sub. The substrate Sub, for example, may include silicon (Si) containing P-type impurities, such as boron (B), or may contain other impurities and materials.

The memory cell array MCA includes the plurality of memory layers ML stacked in the Z-direction and the plurality of transistor layers TL disposed between the memory layers ML and the global bit lines GBL and stacked in the Z-direction. A length in the Z-direction of the memory layer ML and a length in the Z-direction of the transistor layer TL are approximately the same.

Each of between the plurality of memory layers ML and between the plurality of transistor layers TL, an insulating layer 103, such as silicon oxide (SiO₂), is disposed. Between the first memory layer ML from above and the first transistor layer TL from below, an insulating layer 203, such as silicon oxide (SiO₂), is disposed. A length in the Z-direction of the insulating layer 203 is larger than a length in the Z-direction of the insulating layer 103.

### [Structures of Memory Layer ML and Transistor Layer TL]

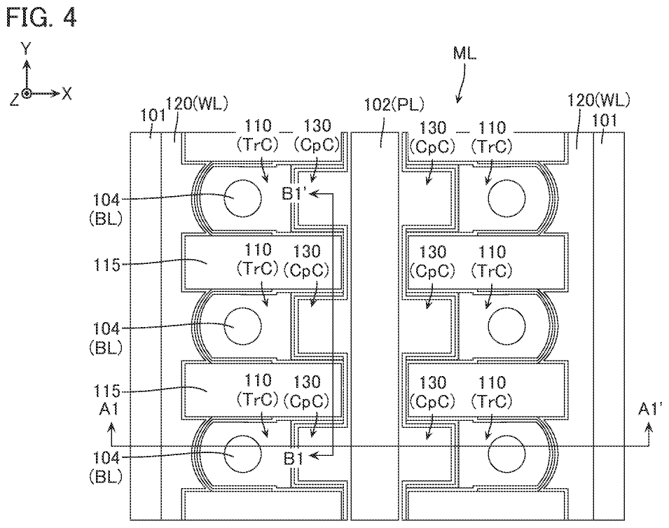

Next, in addition to FIG. 3, with reference to FIG. 4 to FIG. 11, the structures of the memory layer ML and the transistor layer TL are described.

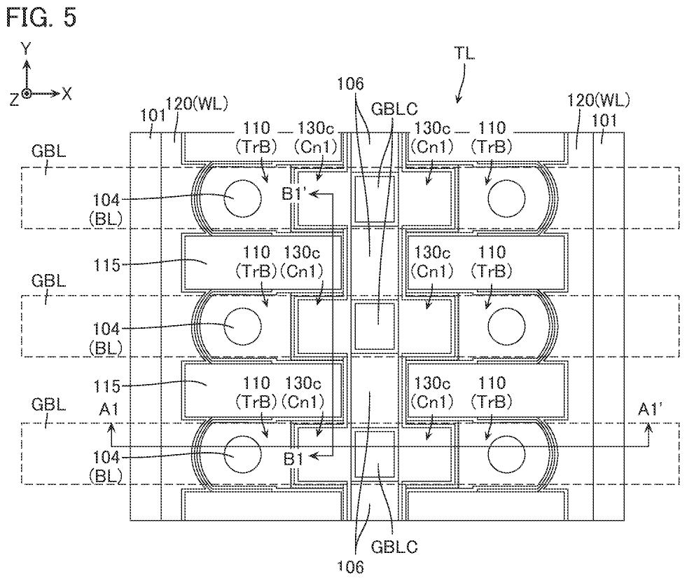

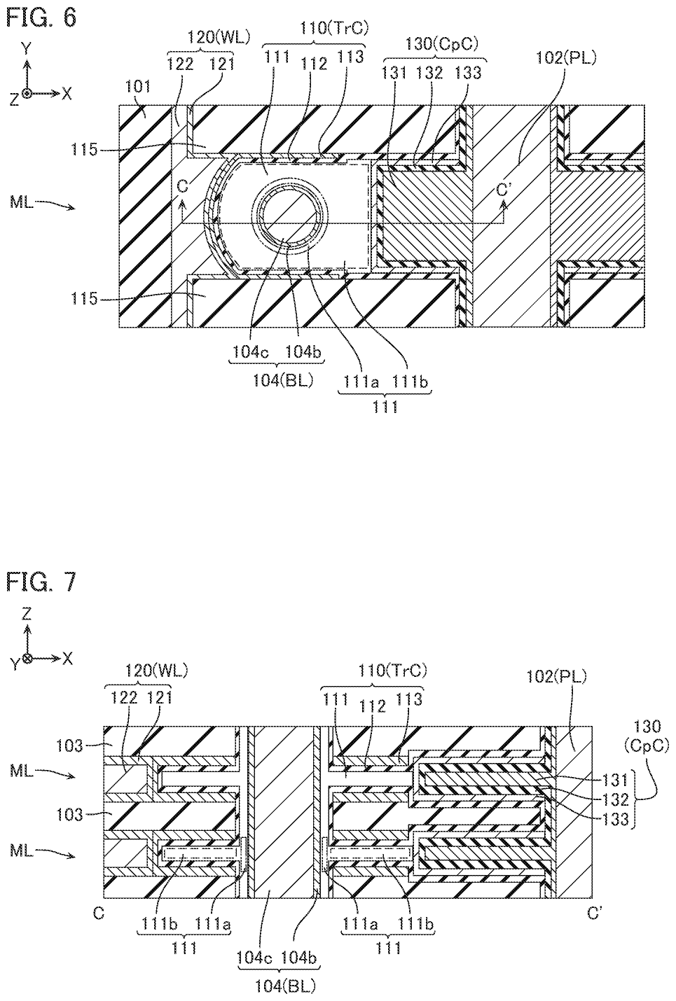

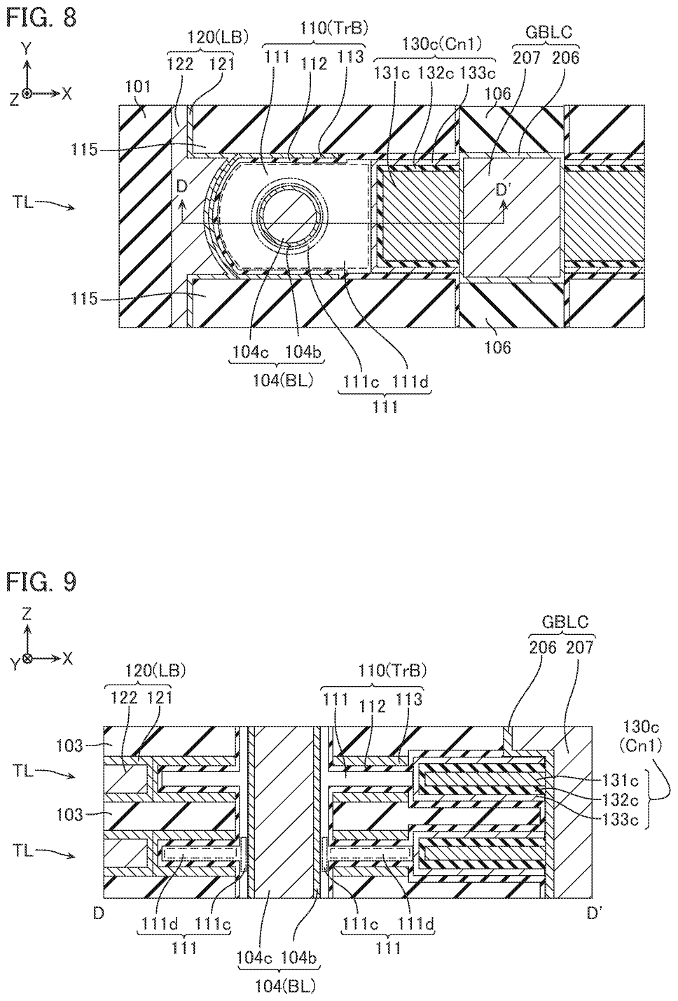

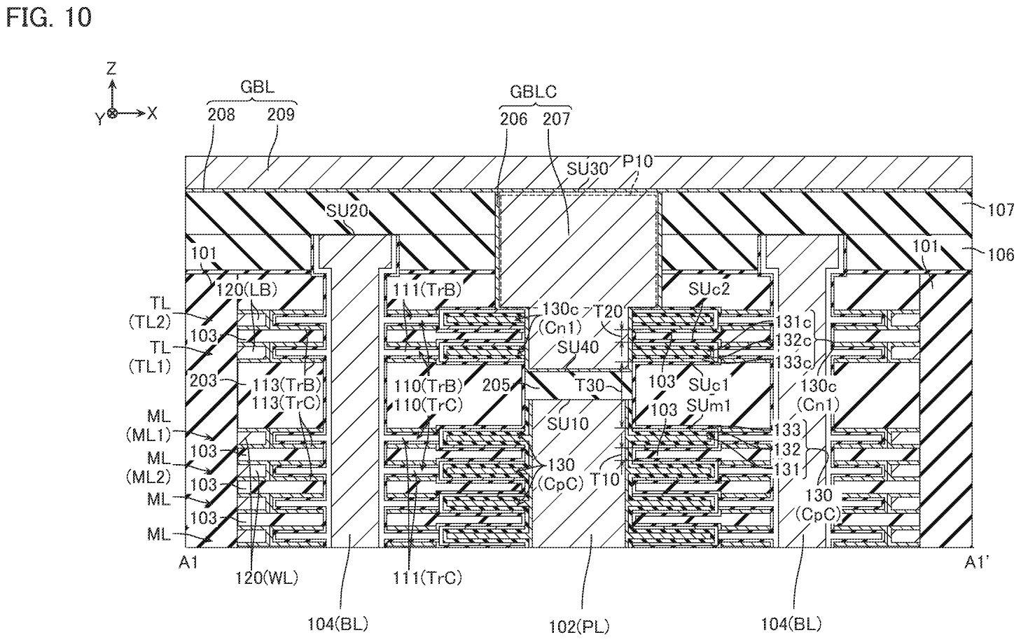

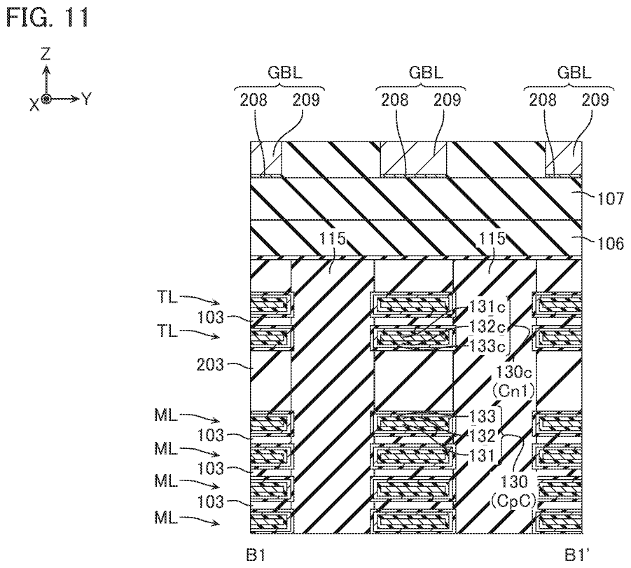

FIG. 4 is a schematic XY cross-sectional view illustrating a configuration of a part the memory layer ML. FIG. 5 is a schematic XY cross-sectional view illustrating a configuration of a part of the transistor layer TL. FIG. 6 is a schematic XY cross-sectional view illustrating a configuration of a part of the memory layer ML and illustrates an enlarged part of FIG. 4. FIG. 7 illustrates a cross-sectional surface of a structure illustrated in FIG. 6 taken along line C-C′ and viewed along an arrow direction. FIG. 8 is a schematic XY cross-sectional view illustrating a configuration of a part of the transistor layer TL and illustrates an enlarged part of FIG. 5. FIG. 9 illustrates a cross-sectional surface of a structure illustrated in FIG. 8 taken along line D-D′ and viewed along an arrow direction. FIG. 10 and FIG. 11 are schematic cross-sectional views illustrating the configuration of the semiconductor memory device according to the embodiment. FIG. 10 illustrates a cross-sectional surface of a structure illustrated in FIG. 4 and FIG. 5 taken along line A1-A1′ and viewed in an arrow direction.

FIG. 11 illustrates a cross-sectional surface of the structure illustrated in FIG. 4 and FIG. 5 taken along line B1-B1′ and viewed in an arrow direction.

As illustrated in FIG. 4, the memory layer ML includes a plurality of insulating layers 101 arranged in the X-direction and a conductive layer 102 disposed between the two insulating layers 101 adjacent in the X-direction. The insulating layer 101 and the conductive layer 102 extend in the Y-direction and the Z-direction and separate the plurality of memory layers ML in the X-direction (see FIG. 10).

As illustrated in FIG. 5, the transistor layer TL includes contacts GBLC and insulating layers 106, such as silicon oxide (SiO₂), disposed between the two insulating layers 101 adjacent in the X-direction and alternately arranged in the Y-direction. The contacts GBLC and the insulating layers 106 extend in the Z-direction and separate the plurality of transistor layers TL in the X-direction (see FIG. 10).

The insulating layer 101 contains, for example, silicon oxide (SiO₂).

The conductive layer 102 includes, for example, a stacked structure of titanium nitride (TiN), silicon germanium (SiGe), and the like. Note that the conductive layer 102, for example, may include a stacked structure of titanium nitride (TiN) and tungsten (W) or may include a stacked structure of titanium nitride (TiN), silicon germanium (SiGe), and tungsten (W). The conductive layer 102, for example, functions as the plate line PL (FIG. 2).

In regions between the insulating layer 101 and the conductive layer 102 (FIG. 4) and between the insulating layer 101, the contacts GBLC, and the insulating layers 106 (FIG. 5), a plurality of via-wirings 104 are disposed. The plurality of via-wirings 104 are arranged in the Y-direction, for example, as illustrated in FIG. 3 and FIG. 10, pass through the plurality of transistor layers TL and the plurality of memory layers ML to extend in the Z-direction.

As illustrated in FIG. 6 and FIG. 8, for example, the via-wiring 104 includes a conductive oxide film 104b containing conductive oxide and a conductive member 104c. The conductive member 104c, for example, may be a stacked structure containing titanium nitride (TiN) and tungsten (W). The conductive member 104c has an approximately columnar shape extending in the Z-direction. The conductive oxide film 104b has an approximately cylindrical shape extending in the Z-direction along an outer peripheral surface of the conductive member 104c. Note that the via-wiring 104 may contain any metal including ruthenium (Ru) and iridium (Ir) instead of the conductive oxide film 104b. The via-wiring 104 may contain only the conductive oxide or may contain only any metal including ruthenium (Ru) and iridium (Ir).

Note that in this specification, the “conductive oxide”, for example, contains indium tin oxide (ITO), indium zinc oxide (IZO), ruthenium oxide (RuO₂), iridium oxide (IrO₂), and any conductive material containing oxygen.

The via-wiring 104, for example, functions as the bit line BL (FIG. 2). For example, as illustrated in FIG. 2, the plurality of bit lines BL are disposed corresponding to the plurality of transistors TrC included in the memory layer ML and the plurality of transistors TrB included in the transistor layer TL.

The memory layer ML and the transistor layer TL include a plurality of transistor structures 110 disposed corresponding to the plurality of via-wirings 104 and a conductive layer 120 disposed on the opposite side of the conductive layer 102 with respect to the plurality of transistor structures 110. The memory layer ML also includes a plurality of capacitor structures 130 disposed between the plurality of transistor structures 110 and the conductive layer 102. The transistor layer TL includes a plurality of electrode structures 130c disposed between the plurality of transistor structures 110 and the plurality of contacts GBLC.

For example, as illustrated in FIG. 6 to FIG. 9, the transistor structure 110 includes a semiconductor layer 111 connected to an outer peripheral surface of the via-wiring 104 and extending in the X-direction, an insulating layer 112 disposed on an upper surface, a lower surface, both side surfaces in the Y-direction, and a side surface on one side in the X-direction (a conductive layer 120 side) of the semiconductor layer 111, and a conductive layer 113 disposed on an upper surface, a lower surface, both side surfaces in the Y-direction, and a side surface on one side in the X-direction (the conductive layer 120 side) of the insulating layer 112.

In an XY cross-sectional surface as exemplified in FIG. 6 and FIG. 8, a side surface on one side in the X-direction (the conductive layer 120 side) of the semiconductor layer 111 may be formed along a circle with a center position of the via-wiring 104 as its center. Additionally, side surfaces on the other side in the X-direction (a conductive layer 102 side) of the semiconductor layer 111, the insulating layer 112, and the conductive layer 113 may be formed in a straight line along a side surface of the conductive layer 102. Both side surfaces in the Y-direction of the semiconductor layer 111, the insulating layer 112, and the conductive layer 113 may be formed in a straight line along a side surface of the insulating layer 115.

The semiconductor layers 111, for example, function as channel regions of the transistors TrC, TrB (FIG. 2). The semiconductor layer 111, for example, may be a semiconductor containing at least one element of gallium (Ga) and aluminum (Al), and containing indium (In), zinc (Zn), and oxygen (O) or may be other oxide semiconductors. The plurality of semiconductor layers 111 arranged in the Z-direction are connected to the via-wiring 104 extending in the Z-direction in common.

For example, as illustrated in FIG. 6 and FIG. 7, in the memory layer ML, the semiconductor layer 111 includes a first part 111a and a second part 111b. The first part 111a extends in the Z-direction and is connected to the outer peripheral surface of the via-wiring 104. The second part 111b extends in the X-direction and is opposed to the conductive layer 113 that functions as a gate electrode of the transistor TrC (FIG. 2) as described later.

For example, as illustrated in FIG. 8 and FIG. 9, in the transistor layer TL, the semiconductor layer 111 includes a third part 111c and a fourth part 111d. The third part 111c extends in the Z-direction and is connected to the outer peripheral surface of the via-wiring 104. The fourth part 111d extends in the X-direction and is opposed to the conductive layer 113 that functions as a gate electrode of the transistor TrB (FIG. 2) as described later.

The insulating layers 112, for example, function as gate insulating films of the transistors TrC, TrB (FIG. 2). The insulating layer 112 contains, for example, silicon oxide (SiO₂).

The conductive layers 113, for example, function as gate electrodes of the transistors TrC, TrB (FIG. 2). The conductive layer 113, for example, contains titanium nitride (TiN) or conductive oxide, such as indium tin oxide (ITO). The plurality of conductive layers 113 arranged in the Y-direction are connected to the conductive layer 120 extending in the Y-direction in common (see FIG. 4 and FIG. 5). The conductive layer 113 is opposed to upper surfaces, lower surfaces, both side surfaces in the Y-direction, and side surfaces on one side in the X-direction (the conductive layer 120 side) of the second part 111b and the fourth part 111d included in the semiconductor layer 111 via the insulating layer 112.

Between the two semiconductor layers 111 adjacent in the Y-direction, an insulating layer 115, such as silicon oxide (SiO₂), is disposed. The insulating layer 115 passes through the plurality of transistor layers TL and the plurality of memory layers ML to extend in the Z-direction.

The conductive layer 120, for example, functions as the word line WL in the memory layer ML and the bit line select line LB (FIG. 2) in the transistor layer TL. The conductive layer 120 extends in the Y-direction and is connected to the plurality of conductive layers 113 arranged in the Y-direction. The conductive layer 120, for example, includes a barrier conductive film 121, such as titanium nitride (TiN), and a conductive film 122 of tungsten (W).

For example, as illustrated in FIG. 6 and FIG. 7, the capacitor structure 130 includes a conductive layer 131, an insulating layer 132 disposed on an upper surface, a lower surface, both side surfaces in the Y-direction, and a side surface on one side in the X-direction (a transistor structure 110 side) of the conductive layer 131, and a conductive layer 133 disposed on an upper surface, a lower surface, both side surfaces in the Y-direction, and a side surface on one side in the X-direction (the transistor structure 110 side) of the insulating layer 132.

The conductive layer 131 functions as one electrode of the capacitor CPC (FIG. 2). The conductive layer 131 includes, for example, a stacked structure of titanium nitride (TiN) and silicon germanium (SiGe), and the like. Note that the conductive layer 131, for example, may include a stacked structure of titanium nitride (TiN) and tungsten (W) or may include a stacked structure of titanium nitride (TiN), silicon germanium (SiGe), and tungsten (W). The conductive layer 131 is continuous with the conductive layer 102.

The insulating layer 132 functions as an insulating layer of the capacitor CPC (FIG. 2). The insulating layer 132, for example, may be zirconia (ZrO₂), alumina (Al₂O₃), or any insulating metal oxide. The insulating layer 132, for example, may be a stacked film (for example, a stacked film of zirconia and alumina) of a plurality of insulating metal oxides.

The conductive layer 133, for example, functions as the other electrode of the capacitor CPC (FIG. 2). The conductive layer 133, for example, contains conductive oxide, such as indium tin oxide (ITO). The conductive layer 133 is insulated from the conductive layer 131 via the insulating layer 132. The conductive layer 133 is connected to a side surface in the X-direction of the semiconductor layer 111. The conductive layer 133 is insulated from the conductive layer 102 via the insulating layer 132.

For example, as illustrated in FIG. 8 and FIG. 9, the electrode structure 130c includes a conductive layer 131c, an insulating layer 132c disposed on an upper surface, a lower surface, both side surfaces in the Y-direction, and a side surface on one side in the X-direction (the transistor structure 110 side) of the conductive layer 131c, and a conductive layer 133c disposed on an upper surface, a lower surface, both side surfaces in the Y-direction, and a side surface on one side in the X-direction (the transistor structure 110 side) of the insulating layer 132c.

The conductive layer 131c contains a material similar to the conductive layer 131. One side in the X-direction (a contact GBLC side) of the conductive layer 131c is in contact with the contact GBLC.

The insulating layer 132c contains a material similar to the insulating layer 132. One side in the X-direction (the contact GBLC side) of the insulating layer 132c is in contact with the contact GBLC.

The conductive layer 133c, for example, functions as a conductive member of the electrode Cn1 (FIG. 2). The conductive layer 133c contains a material similar to the conductive layer 133. A side surface on one side in the X-direction (the transistor structure 110 side) of the conductive layer 133c is connected to a side surface in the X-direction of the semiconductor layer 111. A side surface on the other side in the X-direction (the contact GBLC side) of the conductive layer 133c is connected to the contact GBLC. The conductive layer 133c is electrically connected to the contact GBLC.

For example, as illustrated in FIG. 8 to FIG. 10, the contact GBLC includes a barrier conductive film 206, such as titanium nitride (TiN), and a conductive film 207, such as tungsten (W) or indium tin oxide (ITO). Note that the barrier conductive film 206 and the conductive film 207 may contain conductive oxide, such as indium tin oxide (ITO). The contacts GBLC is connected to the conductive layers 133c included in the plurality of electrode structures 130c arranged in the Z-direction in common at both side surfaces in the X-direction of the contacts GBLC. The contact GBLC is connected to the global bit line GBL at an upper surface. The contacts GBLC, for example, function as electrodes that connect the plurality of transistors TrB to the global bit line GBL via the electrodes Cn1.

Note that, as illustrated in FIG. 10, an upper portion of the contact GBLC may include a part P10 having a wide width in the X-direction. A part of a lower surface of the part P10 may be in contact with a part of an upper surface of the conductive layer 133c included in the first electrode structure 130c from above.

For example, as illustrated in FIG. 5, a width of the contact GBLC in the Y-direction is approximately the same as a width of the global bit line GBL in the Y-direction.

As illustrated in FIG. 10, between the contact GBLC and the conductive layer 102, an insulating layer 205, such as silicon oxide (SiO₂), is disposed. The contact GBLC is insulated from the conductive layer 102 (PL) via the insulating layer 205.

As illustrated in FIG. 3, FIG. 5, FIG. 10, and FIG. 11, the plurality of global bit lines GBL extend in the X-direction and are arranged in the Y-direction. The global bit line GBL, for example, includes a barrier conductive film 208, such as titanium nitride (TiN), and a conductive film 209, such as tungsten (W).

For example, as illustrated in FIG. 5, the global bit line GBL is disposed above the transistor structure 110. The global bit lines GBL are arranged in the Y-direction at a pitch equal to a pitch in which the transistor structures 110 are arranged in the Y-direction. A width of the global bit line GBL in the Y-direction is, for example, approximately the same as a width in the Y-direction of the transistor structure 110.

The plurality of global bit lines GBL arranged in the Y-direction are connected to the respective plurality of contacts GBLC arranged in the Y-direction.

### [Details of Conductive Layer 102 (PL)]

Next, with reference to FIG. 10, a detailed structure of the conductive layer 102 is described.

In the following description, as illustrated in FIG. 10, the first and the second memory layers ML from above are referred to as memory layers ML1, ML2, respectively, in some cases. The first and the second transistor layers from below are referred to as transistor layers TL1, TL2, respectively, in some cases.

The conductive layer 102 has the following structure in which the conductive layer 102 is electrically connected to the plurality of capacitor structures 130 and not electrically connected to the plurality of electrode structures 130c.

The conductive layer 102 has a surface SU10 on an upper surface (FIG. 10). The conductive layer 102 is disposed such that the surface SU10 is disposed between an upper surface of the capacitor structure 130 included in the memory layer ML1 and a lower surface of the electrode structure 130c included in the transistor layer TL1.

The upper surface of the capacitor structure 130 included in the memory layer ML1 has a surface SUm1. The surface SUm1, for example, matches an upper surface of the conductive layer 133 included in the memory layer ML1. The lower surface of the electrode structure 130c included in the transistor layer TL1 has a surface SUc1. The surface SUc1, for example, matches a lower surface of the conductive layer 133c included in the transistor layer TL1.

The surface SU10 is disposed above the surface SUm1 and below the surface SUc1. The surface SU10 is closer to the global bit line GBL than the surface SUm1. The surface SU10 is farther from the global bit line GBL than the surface SUc1.

### [Details of Contact GBLC and Via-Wiring 104 (BL)]

Next, with reference to FIG. 10, detailed structures of the contact GBLC and the via-wiring 104 (BL) are described.

The contact GBLC has the following structure in which the contact GBLC is electrically connected to the plurality of electrode structures 130c and not electrically connected to the plurality of capacitor structures 130.

The contact GBLC has a surface SU40 on a lower surface (FIG. 10). The contact GBLC is disposed such that the surface SU40 is positioned above an upper surface of the capacitor structure 130 included in the memory layer ML1 and below an upper surface of the electrode structure 130c included in the transistor layer TL1.

The upper surface of the electrode structure 130c included in the transistor layer TL1 has a surface SUc2. The surface SU40 is closer to the global bit line GBL than the surface SUm1. The surface SU40 is farther from the global bit line GBL than the surface SUc2.

An upper surface of the via-wiring 104 (BL) has a surface SU20 (FIG. 10). The contact GBLC has a surface SU30 on an upper surface (FIG. 10). The surface SU30 of the contact GBLC is positioned above the surface SU20 of the via-wiring 104. The surface SU30 is closer to the global bit line GBL than the surface SU20.

### [Insulating Layer 103 and Insulating Layer 203]

A length in the Z-direction of the insulating layer 103 disposed between the capacitor structure 130 included in the memory layer ML1 and the capacitor structure 130 included in the memory layer ML2 is a length T10. A length in the Z-direction of the insulating layer 103 disposed between the electrode structure 130c included in the transistor layer TL1 and the electrode structure 130c included in the transistor layer TL2 is a length T20. A length in the Z-direction of the insulating layer 203 disposed between the capacitor structure 130 included in the memory layer ML1 and the electrode structure 130c included in the transistor layer TL1 is a length T30. The length T30 is larger than the length T10 and larger than the length T20.

### [Manufacturing Method]

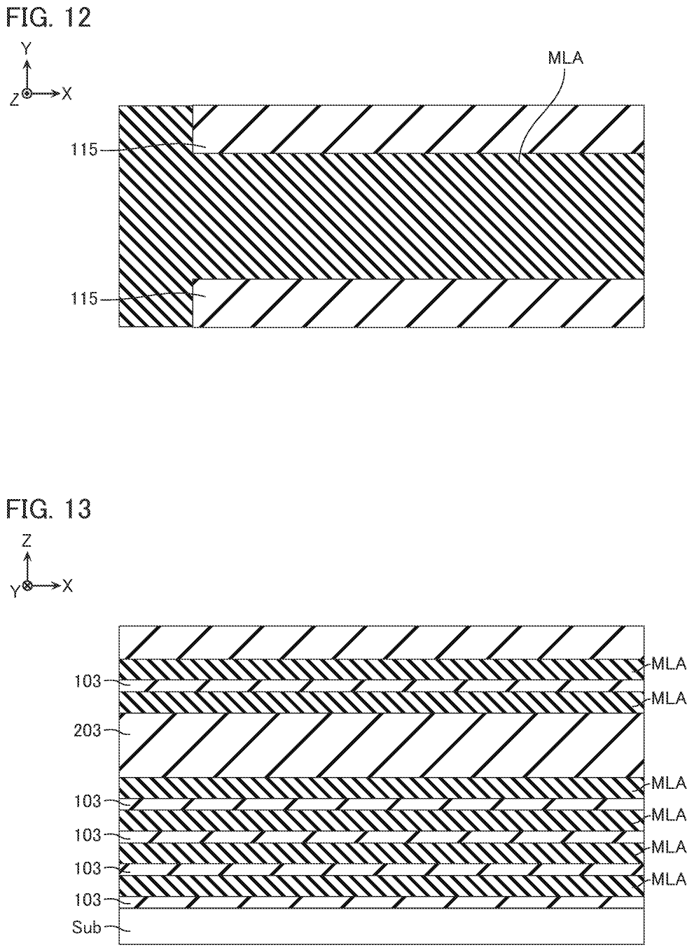

FIG. 12 to FIG. 51 are schematic cross-sectional views for describing the manufacturing method of the semiconductor memory device according to the first embodiment.

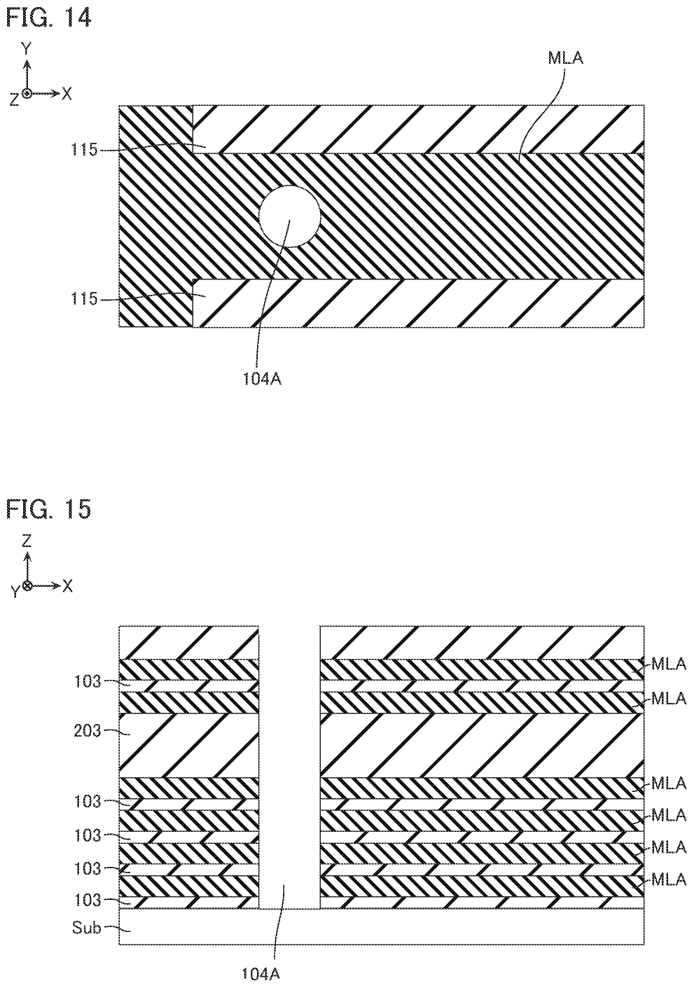

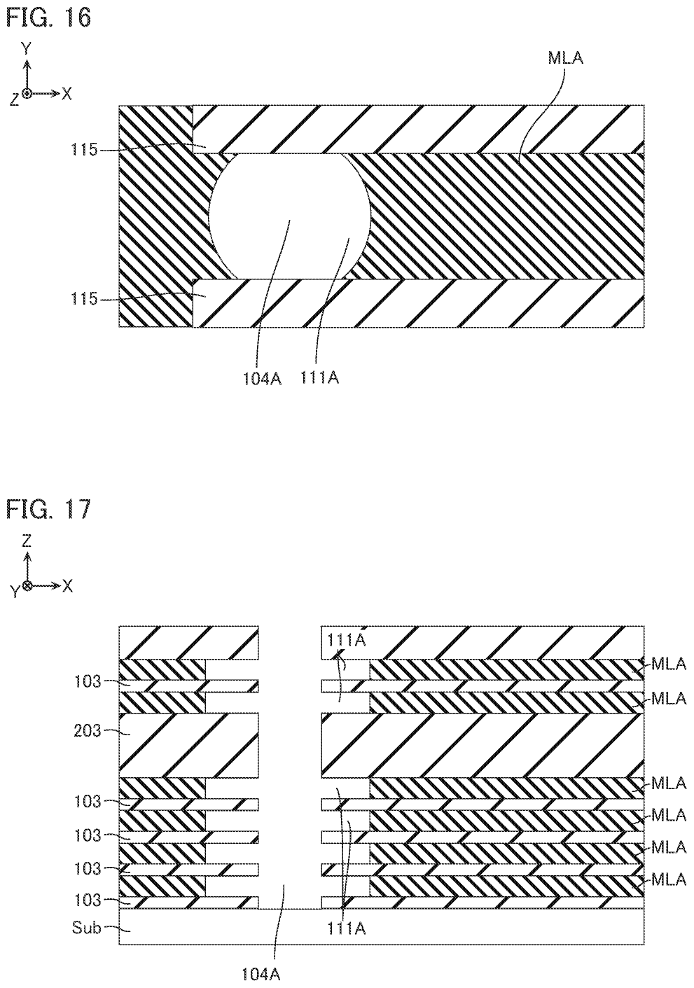

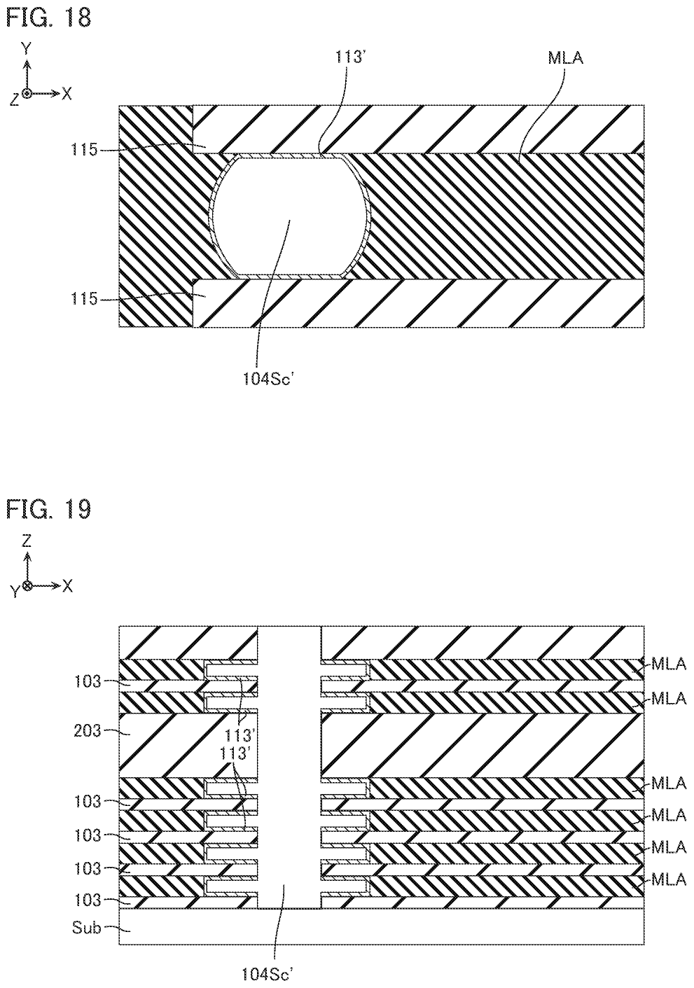

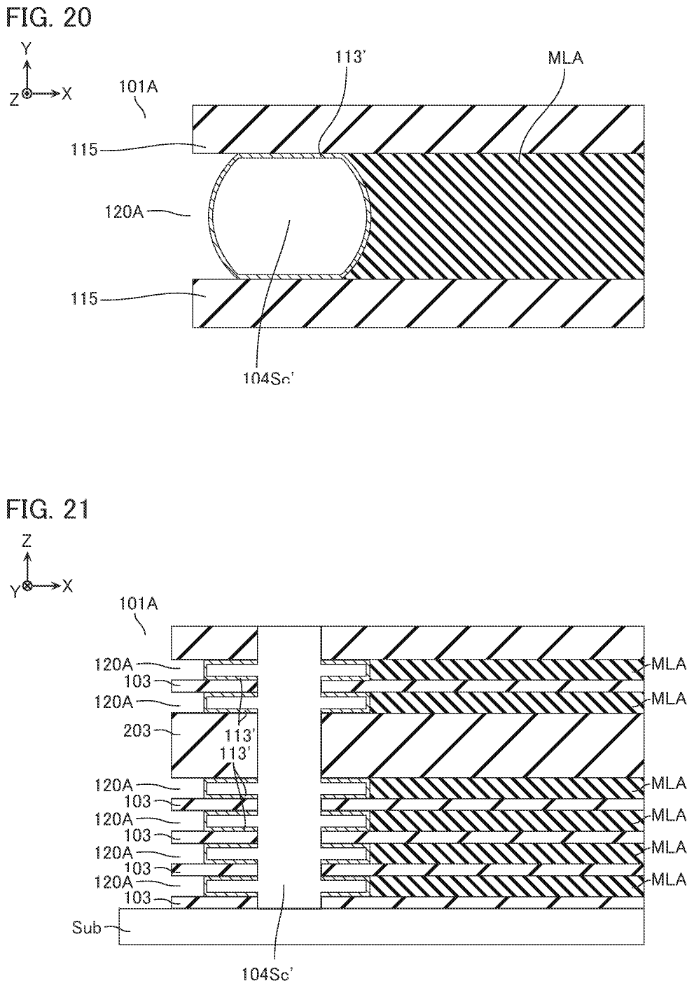

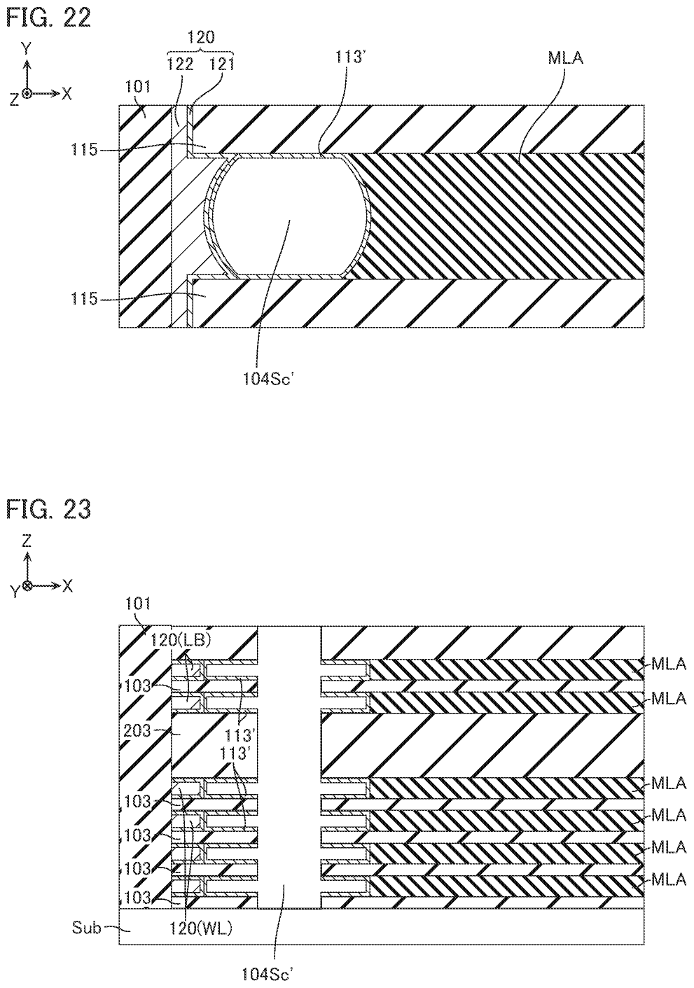

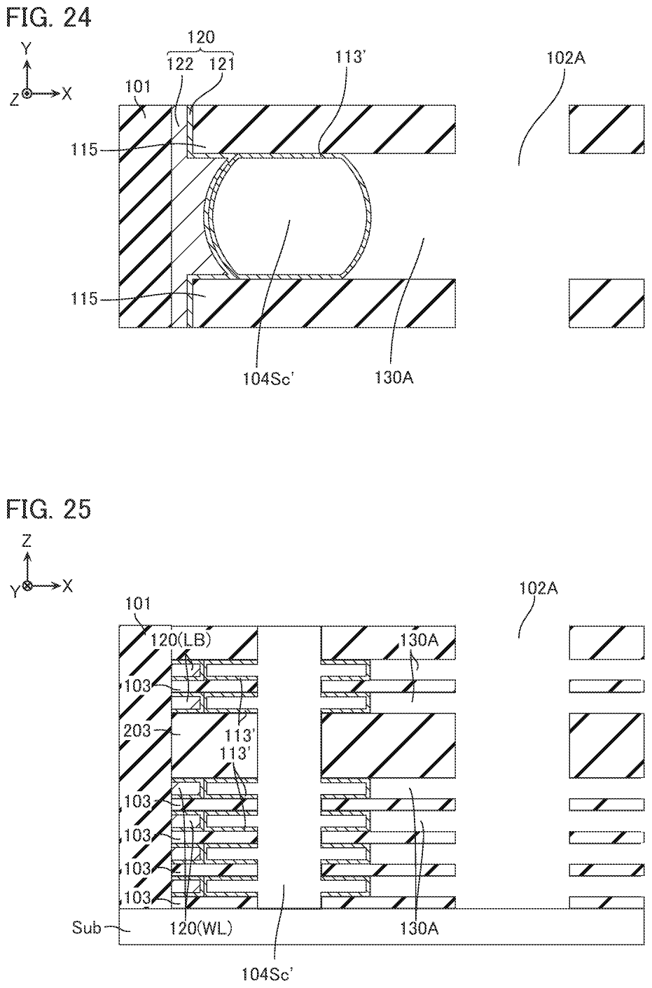

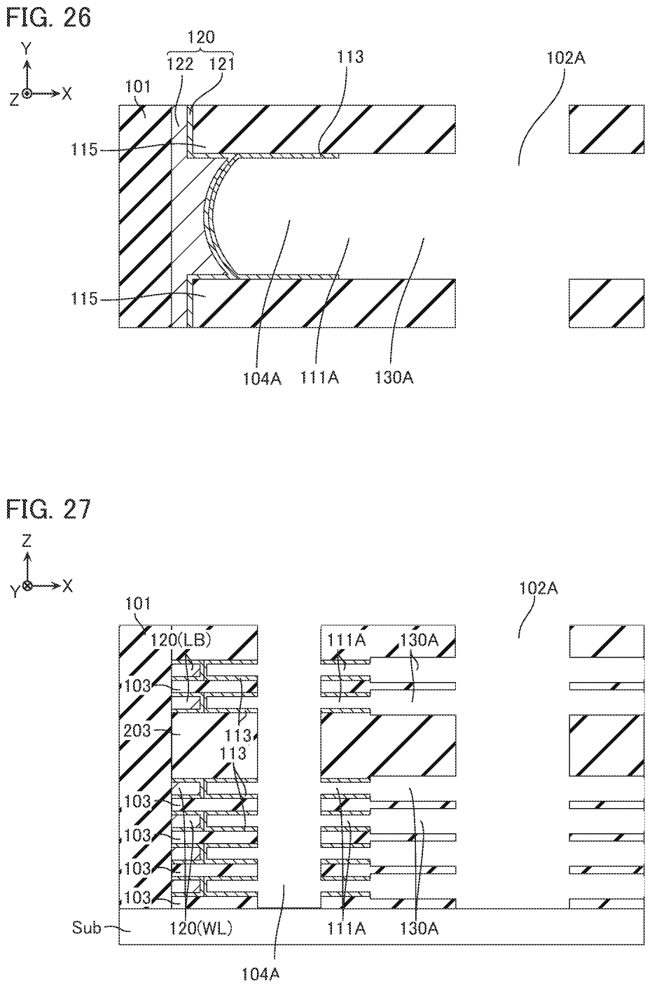

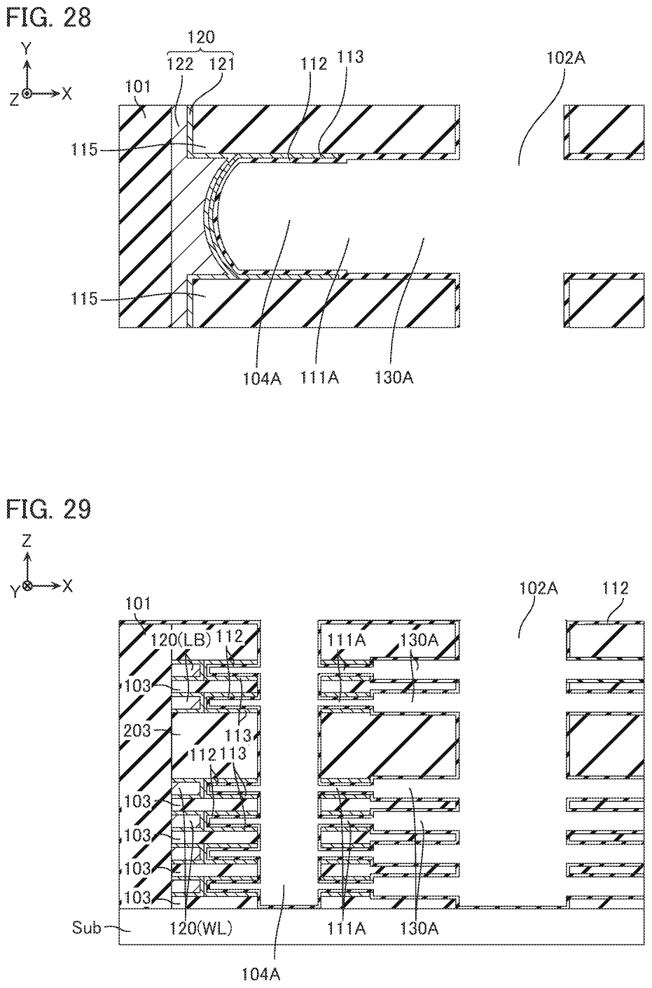

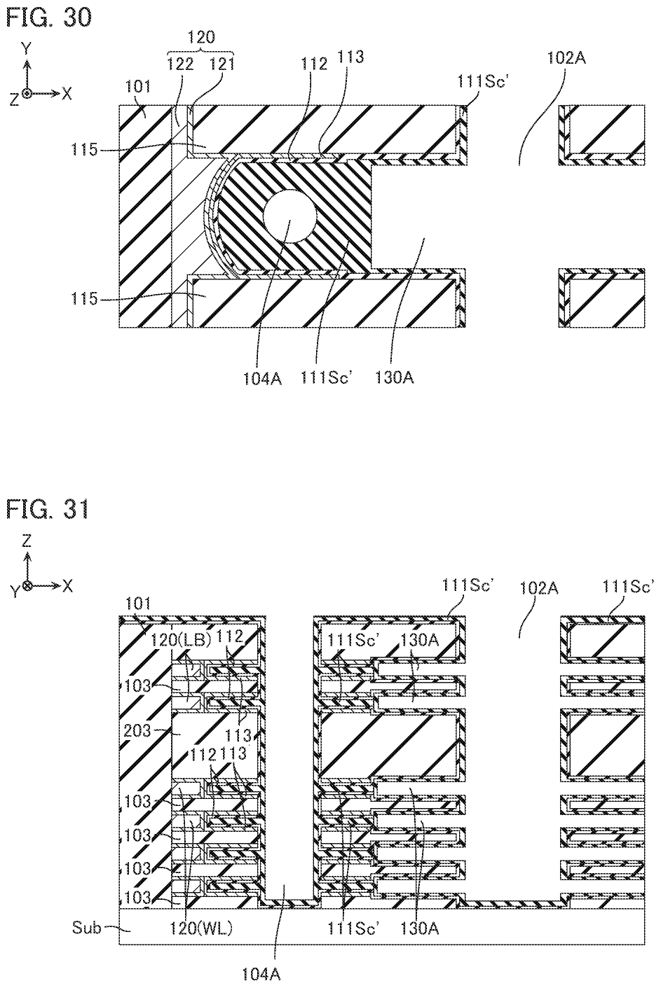

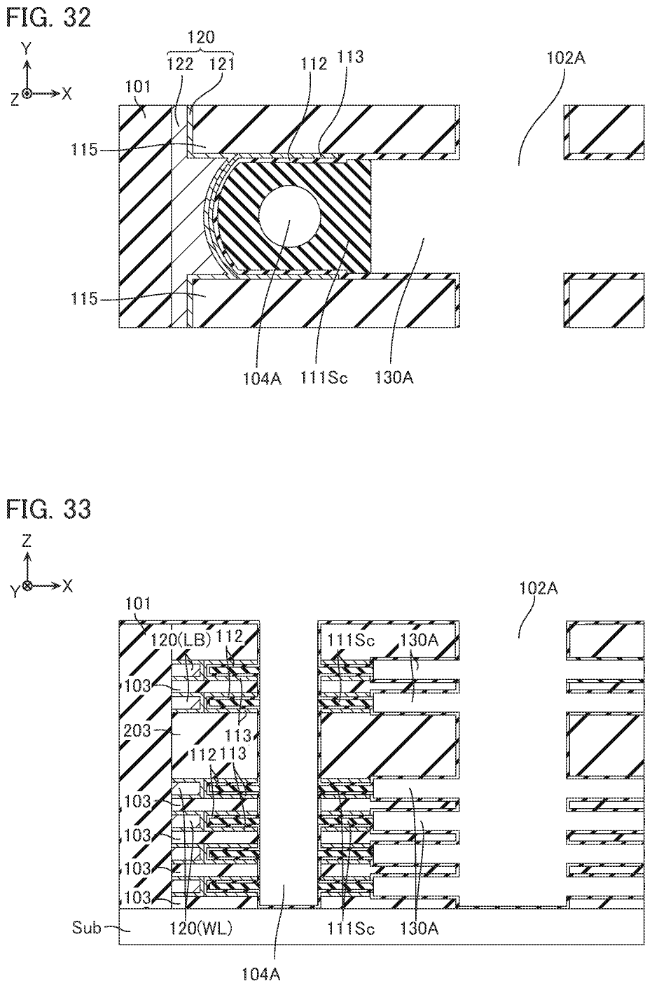

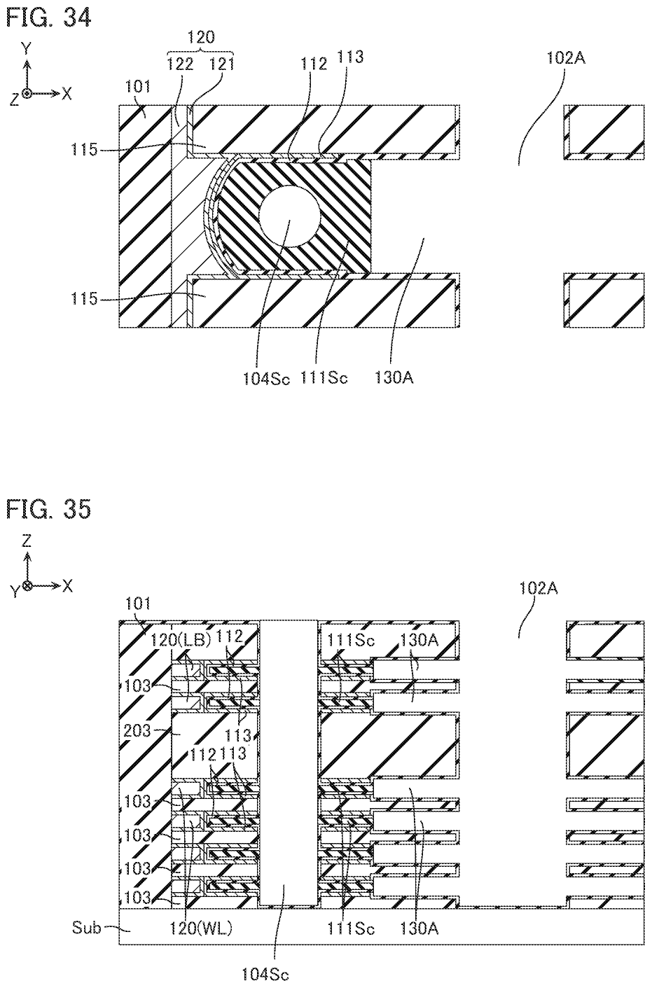

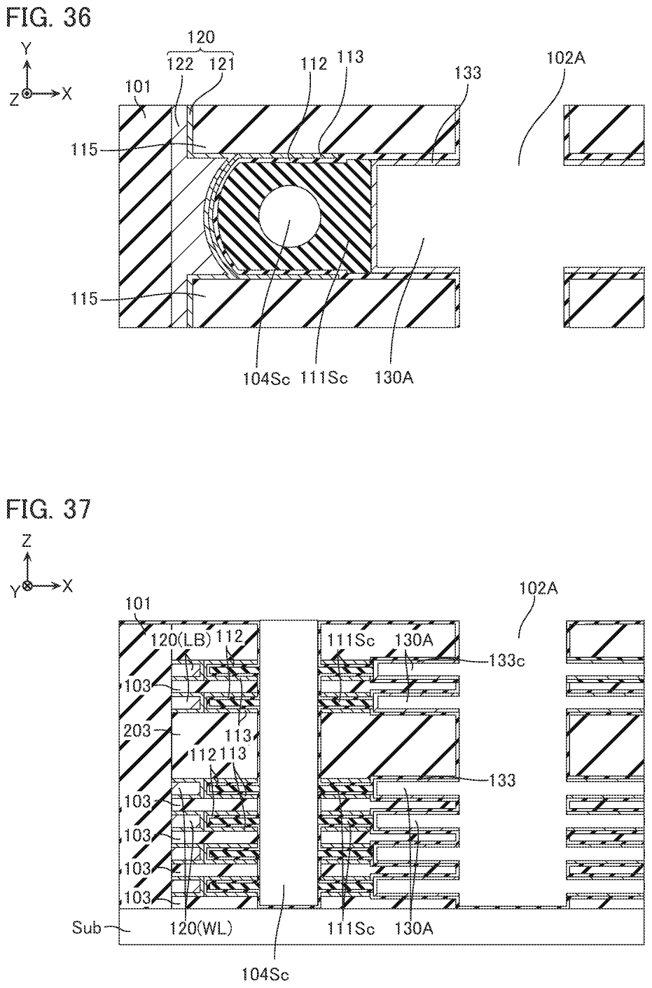

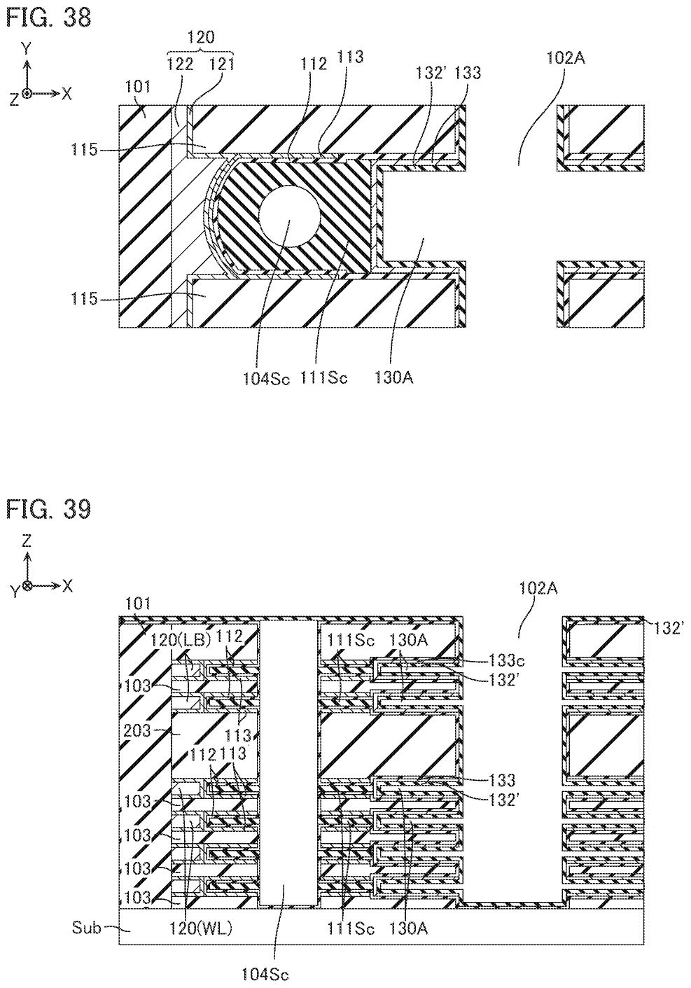

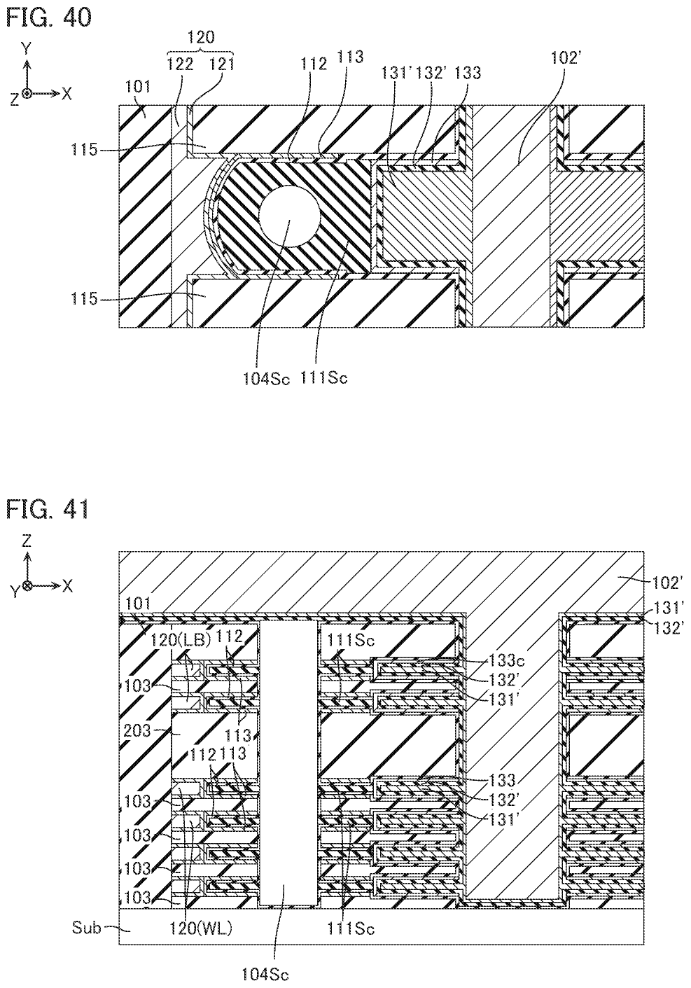

FIG. 12, FIG. 14, FIG. 16, FIG. 18, FIG. 20, FIG. 22, FIG. 24, FIG. 26, FIG. 28, FIG. 30, FIG. 32, FIG. 34, FIG. 36, FIG. 38, and FIG. 40 illustrate cross-sectional surfaces corresponding to FIG. 6 and FIG. 8.

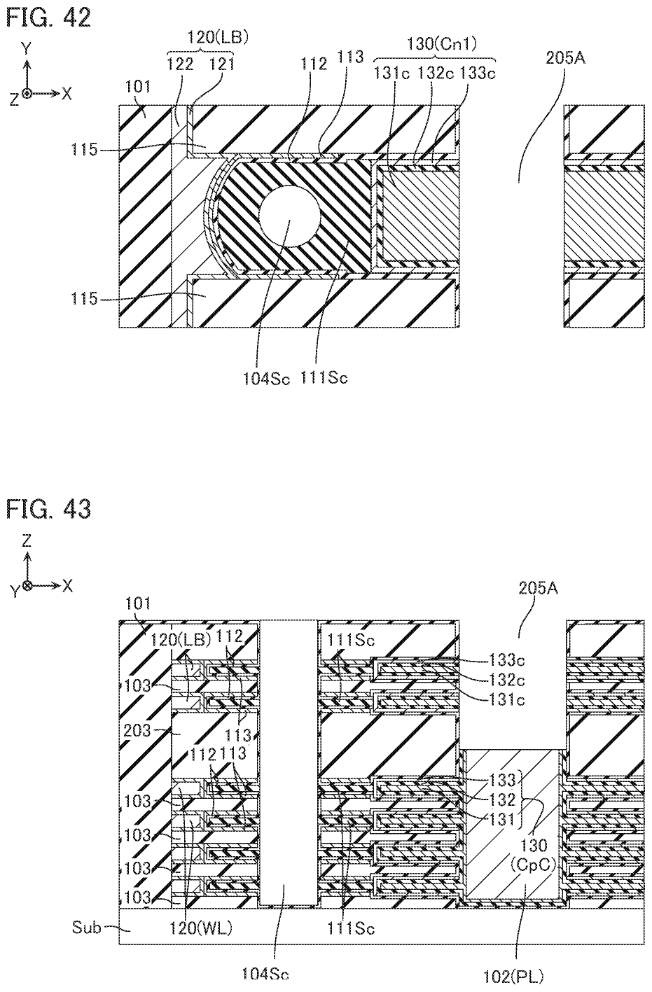

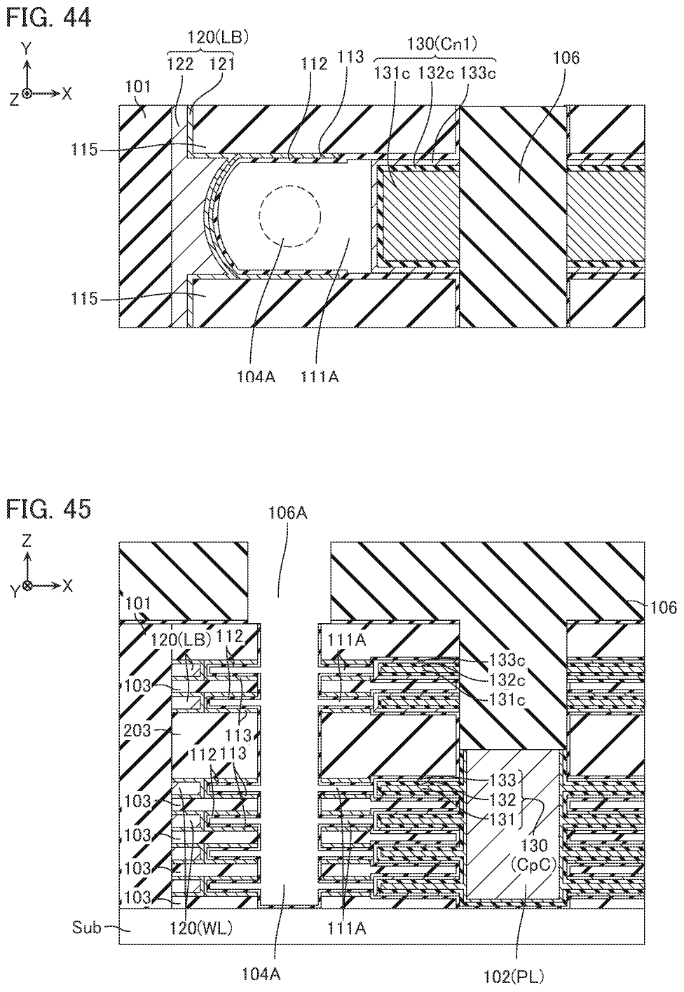

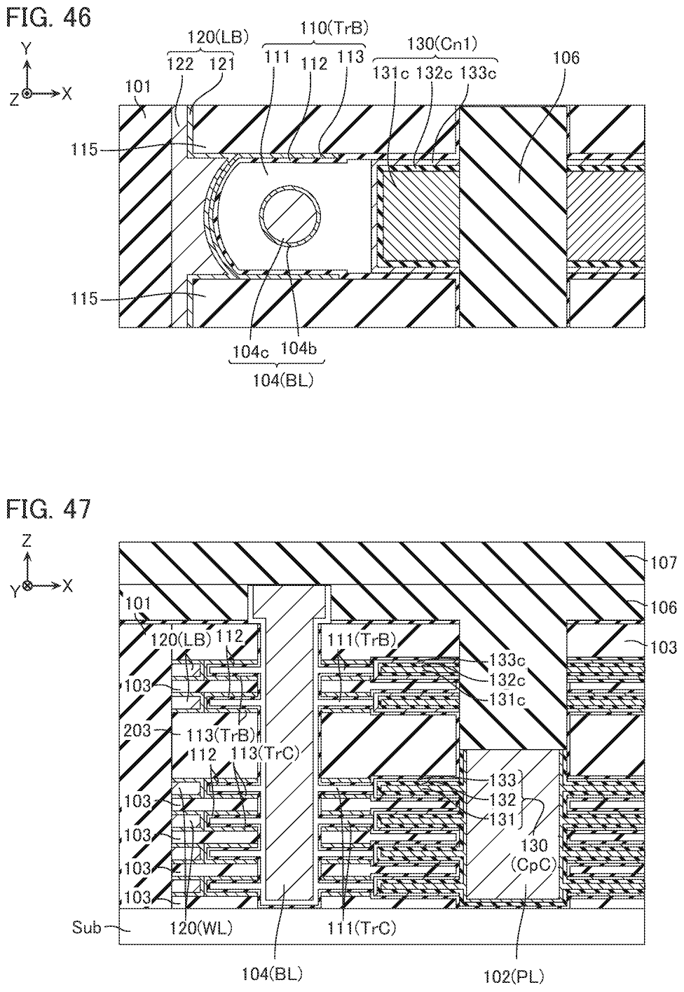

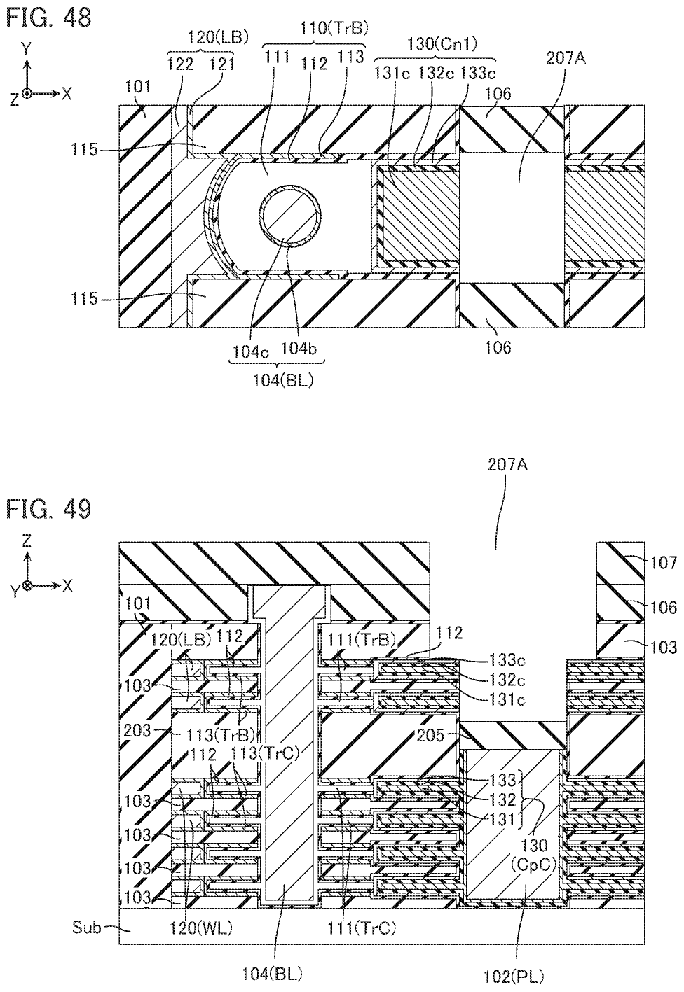

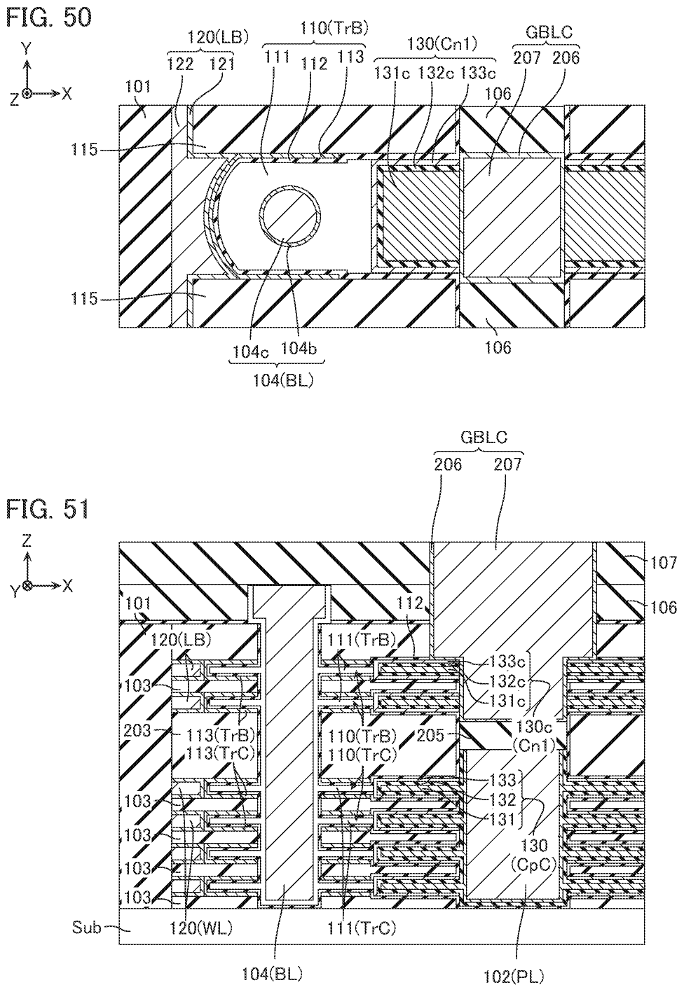

FIG. 42, FIG. 44, FIG. 46, FIG. 48, and FIG. 50 illustrate cross-sectional surfaces corresponding to FIG. 8.

FIG. 13, FIG. 15, FIG. 17, FIG. 19, FIG. 21, FIG. 23, FIG. 25, FIG. 27, FIG. 29, FIG. 31, FIG. 33, FIG. 35, FIG. 37, FIG. 39, FIG. 41, FIG. 43, FIG. 45, FIG. 47, FIG. 49, and FIG. 51 illustrate cross-sectional surfaces corresponding to a part of FIG. 10.

In the manufacturing method, for example, as illustrated in FIG. 13, on an upper surface of the substrate Sub, the plurality of insulating layers 103 and the insulating layer 203 and a plurality of sacrifice layers MLA are alternately formed. The substrate Sub, for example, may be a semiconductor substrate, such as silicon (Si) containing P-type impurities, such as boron (B), or may be a substrate containing other impurities and materials. The sacrifice layer MLA, for example, contains silicon nitride (Si₃N₄) or the like. This process is, for example, performed by Chemical Vapor Deposition (CVD) or the like.

Next, for example, as illustrated in FIG. 12, the insulating layer 115 is formed. In this process, for example, an opening is formed at a position corresponding to the insulating layer 115. This opening extends in the Z-direction and passes through the plurality of insulating layers 103, the insulating layer 203, and the plurality of sacrifice layers MLA stacked in the Z-direction. This process is, for example, performed by Reactive Ion Etching (RIE) or the like. After forming the opening, the insulating layer 115 is formed. This process is, for example, performed by CVD or the like.

Next, for example, as illustrated in FIG. 14 and FIG. 15, an opening 104A is formed at a position corresponding to the via-wiring 104. As illustrated in FIG. 14 and FIG. 15, the opening 104A extends in the Z-direction and passes through the plurality of insulating layers 103, the insulating layer 203, and the plurality of sacrifice layers MLA stacked in the Z-direction. This process is, for example, performed by RIE or the like.

Next, for example, as illustrated in FIG. 16 and FIG. 17, an opening 111A is formed. To the openings 111A, a part of upper surfaces and a part of lower surfaces of the insulating layers 103, 203 and a part of side surfaces of the sacrifice layers MLA in the X-direction are exposed. In this process, for example, via the opening 104A, a part of the sacrifice layers MLA is selectively removed. This process is, for example, performed by wet etching or the like.

Next, for example, as illustrated in FIG. 18 and FIG. 19, a conductive layer 113′ is formed inside the opening 111A and a sacrifice layer 104Sc′ is formed inside the openings 104A, 111A. In this process, for example, a conductive film, such as titanium nitride (TiN), is formed inside the openings 104A, 111A. Next, in the inside of the opening 104A, a part of the conductive films (parts formed on side surfaces of the insulating layers 103, 203) is removed to separate the conductive films in the Z-direction to form the conductive layers 113′. Next, in the openings 104A, 111A, silicon (Si) or the like is embedded to form the sacrifice layer 104Sc′. This process is, for example, performed by CVD and RIE or the like.

Next, for example, as illustrated in FIG. 20 and FIG. 21, an opening 101A and openings 120A are formed at positions corresponding to the insulating layer 101 and the conductive layers 120. To the openings 120A, a part of the upper surfaces and a part of the lower surfaces of the insulating layers 103, 203 and side surfaces in the X-direction of the conductive layers 113′ are exposed. In this process, for example, after the opening 101A is formed, a part of the sacrifice layers MLA is selectively removed via the opening 101A. This process is, for example, performed by RIE and wet etching or the like.

Next, for example, as illustrated in FIG. 22 and FIG. 23, the conductive layers 120 and the insulating layer 101 are formed inside the openings 120A and the opening 101A. In this process, for example, in the inside of the openings 120A, 101A, a conductive film containing a material similar to the conductive layer 120 is formed. Next, in the inside of the opening 101A, a part of the conductive films (parts formed on the side surfaces of the insulating layers 103, 203) is removed to separate the conductive films in the Z-direction and form the conductive layers 120. Next, the insulating layer 101 is embedded into the opening 101A. This process is, for example, performed by a method, such as CVD and RIE.

Next, for example, as illustrated in FIG. 24 and FIG. 25, an opening 102A is formed at a position corresponding to a part of the conductive layer 102, the insulating layer 205, and the contact GBLC. The opening 102A extends in the Z-direction and passes through the plurality of insulating layers 103, the insulating layer 203, and the plurality of sacrifice layers MLA stacked in the Z-direction. This process is, for example, performed by RIE or the like.

For example, as illustrated in FIG. 24 and FIG. 25, openings 130A are formed. To the openings 130A, a part of the upper surfaces and a part of the lower surfaces of the insulating layers 103, 203 and a part of side surfaces in the X-direction of the conductive layers 113′ are exposed. In this process, for example, a part of the sacrifice layers MLA are selectively removed via the opening 102A. This process is, for example, performed by wet etching or the like.

Next, for example, as illustrated in FIG. 26 and FIG. 27, a part of the upper surfaces and a part of the lower surfaces of the insulating layers 103, 203 and a part of the side surfaces in the X-direction of the conductive layers 113′ exposed to the openings 130A are removed. This process expands a width of the opening 130A in the Z-direction. This process is, for example, performed by wet etching or the like.

For example, as illustrated in FIG. 26 and FIG. 27, the sacrifice layer 104Sc′ is removed to form the openings 104A, 111A. By this process, the openings 102A, 104A, 111A, 130A are communicated. This process is, for example, performed by wet etching or the like.

Next, for example, as illustrated in FIG. 28 and FIG. 29, the insulating layer 112 is formed inside the openings 102A, 104A, 111A, 130A. This process is, for example, performed by CVD or the like.

Next, for example, as illustrated in FIG. 30 and FIG. 31, a sacrifice layer 111Sc′, such as silicon nitride (Si₃N₄) or titanium nitride (TiN), is formed inside the openings 102A, 104A, 111A, 130A. In this process, the opening 111A is filled with the sacrifice layer 111Sc′, and the opening 102A, 104A, 130A is not filled with the sacrifice layer 111Sc′. This process is, for example, performed by CVD or the like.

Next, for example, as illustrated in FIG. 32 and FIG. 33, via the openings 102A, 104A, a part of the sacrifice layer 111Sc′ is removed to separate the sacrifice layer 111Sc′ in the Z-direction and form a sacrifice layer 111Sc, such as silicon nitride (Si₃N₄) or titanium nitride (TiN). This process is, for example, performed by wet etching or the like.

Next, for example, as illustrated in FIG. 34 a FIG. 35, silicon (Si) or the like is embedded into the opening 104A to form a sacrifice layer 104Sc. In this process, for example, silicon (Si) or the like is embedded into the openings 102A, 104A, and after that the silicon (Si) or the like embedded into the opening 102A is removed. This process is, for example, performed by CVD, wet etching, or the like.

Next, for example, as illustrated in FIG. 36 and FIG. 37, the conductive layers 133, 133c are formed inside the opening 130A. In this process, for example, a conductive oxide layer, such as indium tin oxide (ITO), is formed inside the openings 102A, 130A, for example. Next, in the inside of the opening 102A, a part of the conductive oxide layer (a part formed on the side surfaces of the insulating layers 103, 203) is removed to separate the conductive oxide layer in the Z-direction and form the conductive layers 133, 133c. This process is, for example, performed by CVD, RIE, or the like.

Next, for example, as illustrated in FIG. 38 and FIG. 39, an insulating layer 132′ containing a material similar to the insulating layer 132 is formed inside the opening 102A, 130A and an upper surface of a structure illustrated in FIG. 37. This process is, for example, performed by CVD or the like.

Next, for example, as illustrated in FIG. 40 and FIG. 41, a conductive layer 131′ containing a material similar to the conductive layer 131 is formed inside the openings 102A, 130A, and next, a conductive layer 102′ containing a material similar to the conductive layer 102 is formed inside the opening 102A. In this process, the opening 130A is filled with the conductive layer 131′, and the opening 102A is not filled with the conductive layer 131′. This process is, for example, performed by CVD or the like.

Next, for example, as illustrated in FIG. 42 and FIG. 43, a part of the conductive layer 102′, the conductive layer 131′, and the insulating layer 132′ is removed to form the conductive layers 131, 131c, the insulating layers 132, 132c, the conductive layer 102, and an opening 205A. This process is, for example, performed by RIE or the like.

Next, for example, as illustrated in FIG. 44 and FIG. 45, the insulating layer 106 is formed inside the opening 205A and an upper surface of a structure illustrated in FIG. 43. Next, in the insulating layer 106, a part positioned at an upper portion of the sacrifice layer 104Sc is removed to form an opening 106A, the sacrifice layers 104Sc, 111Sc are removed via the opening 106A to form the openings 104A, 111A. This process is, for example, performed by CVD, RIE, wet etching, or the like.

Next, for example, as illustrated in FIG. 46 and FIG. 47, the semiconductor layer 111 is formed inside the openings 104A, 111A. The opening 111A is filled with the semiconductor layer 111. On the other hand, the opening 104A is not filled with the semiconductor layer 111. This process is, for example, performed by Atomic Layer Deposition (ALD) or the like.

For example, as illustrated in FIG. 46 and FIG. 47, the via-wiring 104 (the conductive oxide film 104b and the conductive member 104c) is formed inside the openings 104A, 106A and after an upper surface is planarized, an insulating layer 107 is formed on upper surfaces of the insulating layer 106 and the via-wiring 104. This process is, for example, performed by a method, such as CVD and Chemical Mechanical Polishing (CMP).

Next, for example, as illustrated in FIG. 48 and FIG. 49, among the insulating layers 107, 106, 103, parts corresponding to the contact GBLC are removed to form the insulating layer 205 and an opening 207A. This process is, for example, performed by RIE or the like.

Note that, in this process, a part of the insulating layer 112 in contact with an upper surface of the first electrode structure 130c from above is simultaneously removed to expose a part of an upper surface of the conductive layer 133c included in first electrode structure 130c from above.

Next, for example, as illustrated in FIG. 50 and FIG. 51, the contact GBLC (the barrier conductive film 206 and the conductive film 207) is formed inside the opening 207A. This process is, for example, performed by CVD, CMP, or the like.

Next, on an upper surface of a structure illustrated in FIG. 51, the global bit line GBL (the barrier conductive film 208 and the conductive film 209) is formed. A structure above the global bit line GBL is formed, and after that the plurality of first bonding electrodes P_{I1} as illustrated in FIG. 1 are form on a surface of the chip C_{M}.

Next, a wafer including the chip C_{M} on which the memory cell array MCA is formed by the above-described processes and a wafer including the chip C_{P} are bonded in the relationship as illustrated in FIG. 1, and after that, the plurality of external pad electrodes P_{X} or the like are formed.

Thus, the structure described with reference to FIG. 1 to FIG. 11 is formed.

### Effects

In the semiconductor memory device according to the embodiment, between the bit line BL and the global bit line GBL, the plurality of transistors TrB are connected in parallel. The plurality of transistors TrB connected in parallel are simultaneously turned ON to electrically conduct the bit line BL and the global bit line GBL, and thus a summed value of currents flowing from the bit line BL to the global bit line GBL during electrical conduction can be increased. With this configuration, a voltage can be transferred at high speed to the selected bit line BL and global bit line GBL.

In the embodiment, the structure inside the transistor layer TL is configured similarly to the structure in the memory layer ML. Therefore, the semiconductor memory device according to the embodiment is inexpensively achievable without an increase in the number of manufacturing processes.

### Second Embodiment

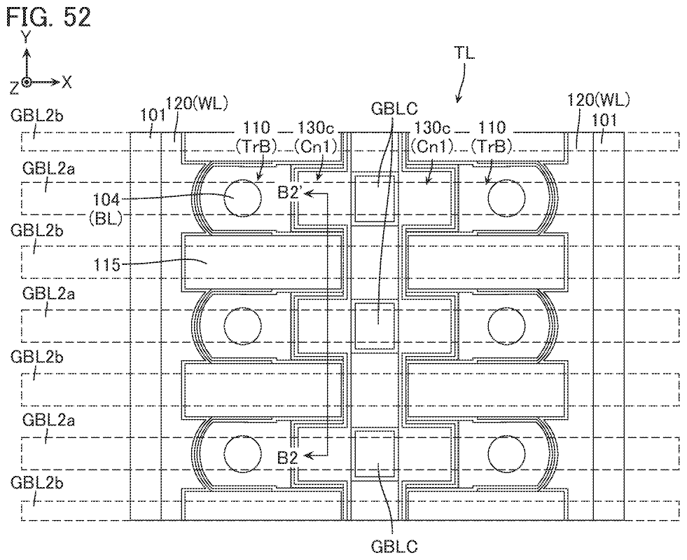

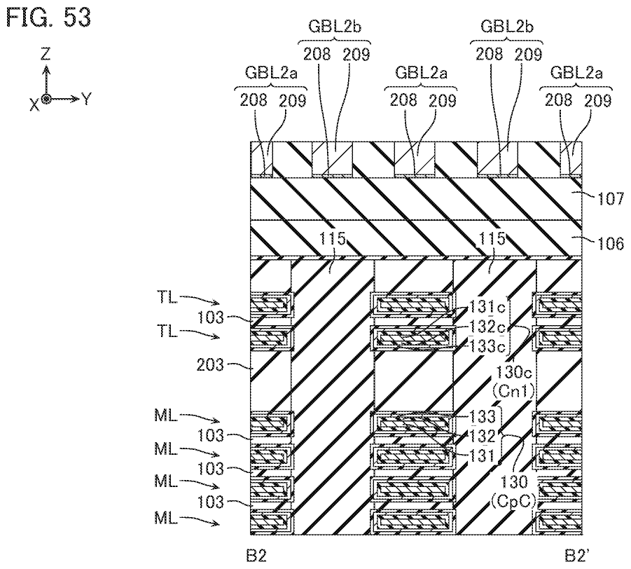

FIG. 52 and FIG. 53 are schematic cross-sectional views illustrating configurations of parts of a semiconductor memory device according to the second embodiment. FIG. 53 illustrates a cross-sectional surface of a structure illustrated in FIG. 52 taken along line B2-B2′ and viewed along an arrow direction. In the following description, a similar reference numeral is given to a part similar to the first embodiment, and the description thereof is omitted.

The semiconductor memory device according to the second embodiment is configured basically similarly to the semiconductor memory device according to the first embodiment. However, the semiconductor memory device according to the second embodiment includes global bit lines GBL2a, GBL2b alternately arranged in the Y-direction instead of the global bit lines GBL.

The global bit lines GBL2a, GBL2b are configured basically similarly to the global bit lines GBL. However, widths in the Y-direction of the global bit lines GBL2a, GBL2b are, for example, approximately the half of a width in the Y-direction of the transistor structure 110.

The global bit line GBL2a is, for example, disposed above the transistor structure 110. The global bit line GBL2b is, for example, disposed above the insulating layer 115. The global bit lines GBL2a, GBL2b are alternately arranged in the Y-direction at a pitch half of a pitch of the transistor structures 110 arranged in the Y-direction.

For example, in a region illustrated in FIG. 52, the plurality of global bit lines GBL2a arranged in the Y-direction are connected to the respective plurality of contacts GBLC arranged in the Y-direction. On the other hand, for example, in a region illustrated in FIG. 52, the plurality of global bit lines GBL2b arranged in the Y-direction are unconnected to the contacts GBLC.

### Third Embodiment

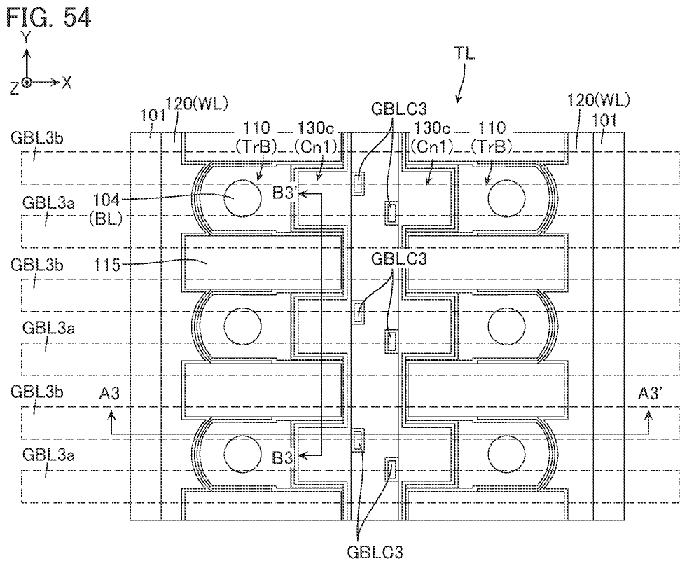

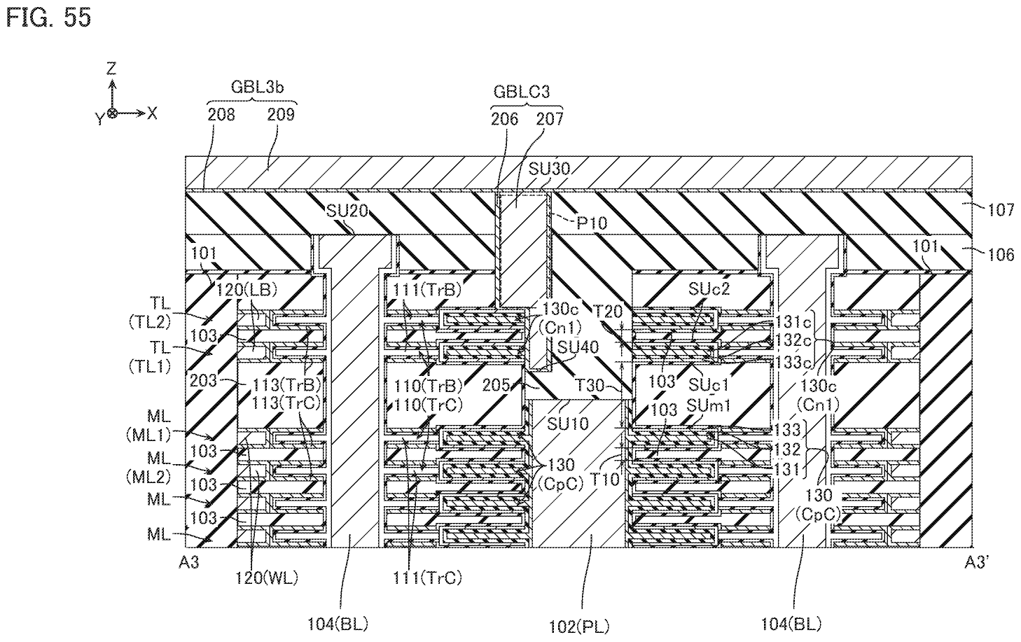

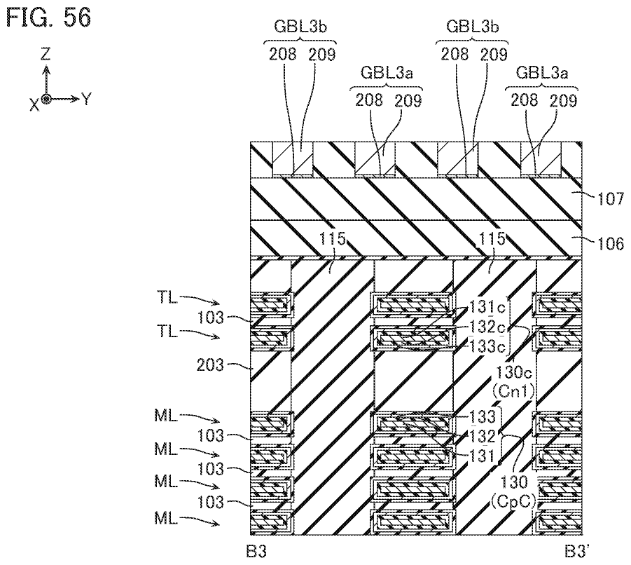

FIG. 54 to FIG. 56 are schematic cross-sectional views illustrating configurations of parts of a semiconductor memory device according to the third embodiment. FIG. 55 illustrates a cross-sectional surface of a structure illustrated in FIG. 54 taken along line A3-A3′ and viewed along an arrow direction. FIG. 56 illustrates a cross-sectional surface of a structure illustrated in FIG. 54 taken along line B3-B3′ and viewed along an arrow direction. In the following description, a similar reference numeral is given to a part similar to the first embodiment, and the description thereof is omitted.

The semiconductor memory device according to the third embodiment is configured basically similarly to the semiconductor memory device according to the first embodiment. However, the semiconductor memory device according to third embodiment includes a contact GBLC3 instead of the contact GBLC and global bit lines GBL3a, GBL3b alternately arranged in the Y-direction instead of the global bit lines GBL.

The contact GBLC3 is configured basically similarly to the contact GBLC. However, the contact GBLC3 has widths in the X-direction and the Y-direction smaller than those of the contact GBLC. A width in the Y-direction of the contact GBLC3 is, for example, approximately the half of a width in the Y-direction of the transistor structure 110 as illustrated in FIG. 54.

For example, as illustrated in FIG. 54, the contacts GBLC3 are displaced one by one in X-direction positive side and negative side and arranged in the Y-direction. The contact GBLC3 disposed at the X-direction negative side is disposed at a Y-direction positive side with respect to the via-wiring 104, and the contact GBLC3 disposed at the X-direction positive side is disposed at a Y-direction negative side with respect to the via-wiring 104.

For example, as illustrated in FIG. 55, the contact GBLC3 is connected in common to the plurality of electrode structures 130c arranged in the Y-direction at a side surface on one side in the X-direction (the via-wiring 104 side) of the contact GBLC3.

The global bit lines GBL3a, GBL3b are configured basically similarly to the global bit lines GBL.

However, for example, as illustrated in FIG. 54 and FIG. 56, the global bit lines GBL3a, GBL3b are disposed above the transistor structures 110 and the insulating layers 101 across a region in the Y-direction where the transistor structures 110 and the insulating layers 101 are disposed. The global bit lines GBL3a, GBL3b are alternately arranged in the Y-direction at a pitch half of the pitch of the transistor structures 110 arranged in the Y-direction. Widths in the Y-direction of the global bit lines GBL3a, GBL3b are, for example, approximately the half of the width in the Y-direction of the transistor structure 110.

For example, in a region illustrated in FIG. 54, the plurality of global bit lines GBL3a, GBL3b arranged in the Y-direction are connected to the respective plurality of contacts GBLC3 arranged in the Y-direction.

### Fourth Embodiment

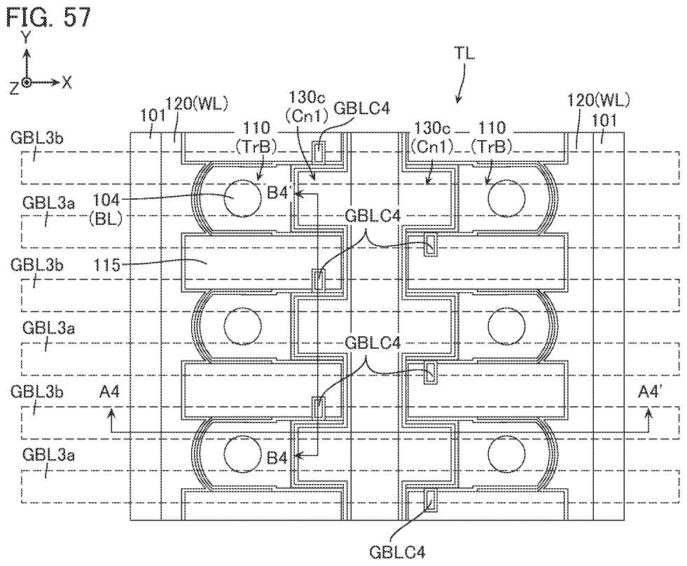

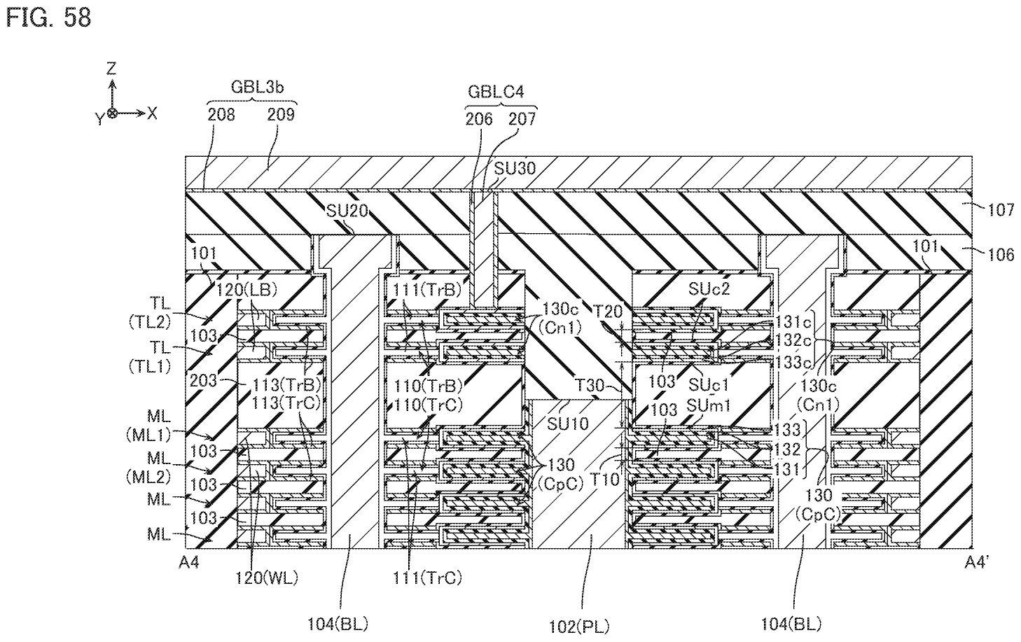

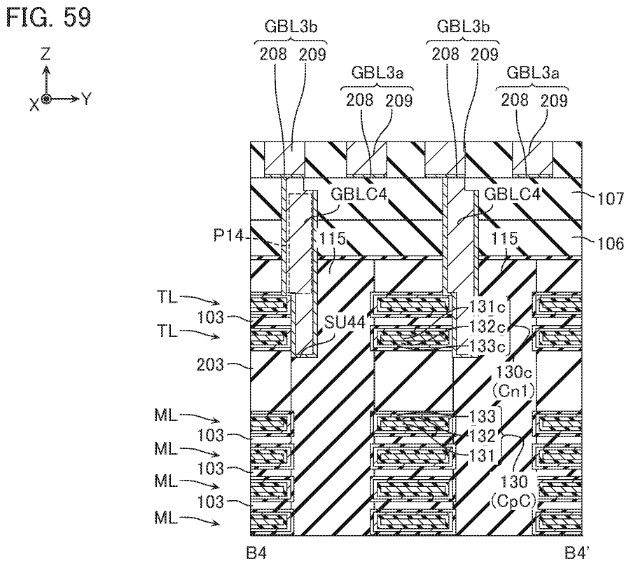

FIG. 57 to FIG. 59 are schematic cross-sectional views illustrating configurations of parts of a semiconductor memory device according to the fourth embodiment. FIG. 58 illustrates a cross-sectional surface of a structure illustrated in FIG. 57 taken along line A4-A4′ and viewed along an arrow direction. FIG. 59 illustrates a cross-sectional surface of a structure illustrated in FIG. 57 taken along line B4-B4′ and viewed along an arrow direction. In the following description, a similar reference numeral is given to a part similar to the third embodiment, and the description thereof is omitted.

The semiconductor memory device according to the fourth embodiment is configured basically similarly to the semiconductor memory device according to the third embodiment. However, the semiconductor memory device according to the fourth embodiment includes contacts GBLC4 instead of the contacts GBLC3.

The contact GBLC4 is configured basically similarly to the contact GBLC3.

However, as illustrated in FIG. 57 and FIG. 59, the contact GBLC4 is disposed inside the insulating layer 115 in the transistor layer TL. For example, as illustrated in FIG. 59, the contact GBLC4 is connected to the electrode structure 130c from one side in the Y-direction (the Y-direction positive side or the Y-direction negative side).

For example, as illustrated in FIG. 59, an upper portion of the contact GBLC4 may include a part P14 having a wide width in the Y-direction at an upper portion. A part of a lower surface of the part P14 may be in contact with a part of an upper surface of the conductive layer 133c included in the first electrode structure 130c from above.

The contact GBLC4 has a surface SU44 on a lower surface (FIG. 59). The contact GBLC4 is disposed such that the surface SU44 is positioned above an upper surface of the capacitor structure 130 included in the memory layer ML1 and below an upper surface of the electrode structure 130c included in the transistor layer TL1.

### Fifth Embodiment

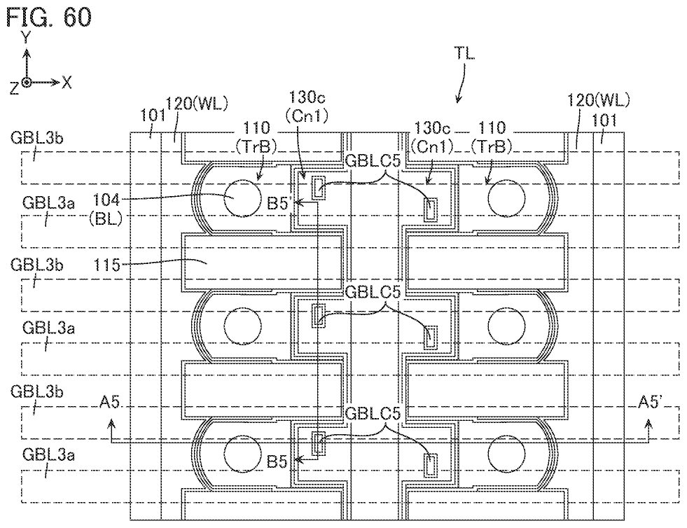

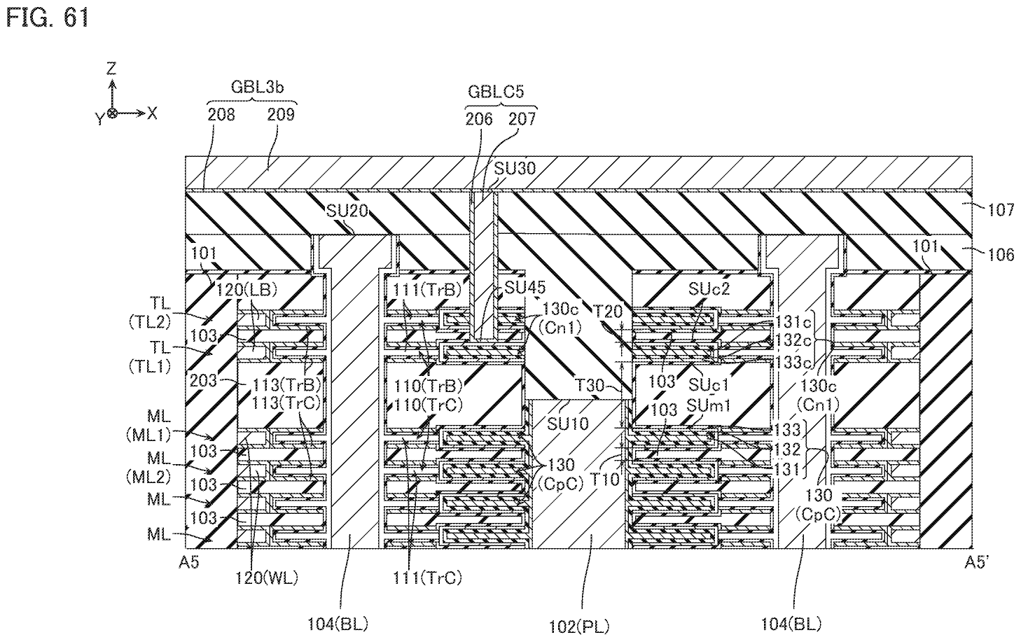

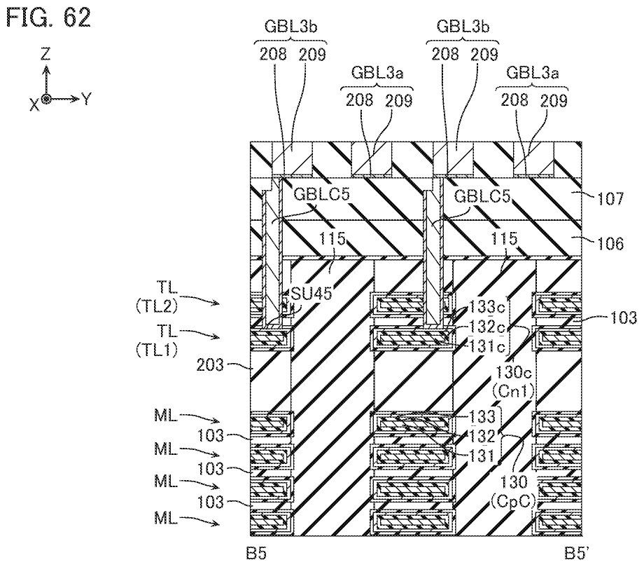

FIG. 60 to FIG. 62 are schematic cross-sectional views illustrating configurations of parts of a semiconductor memory device according to the fifth embodiment. FIG. 61 illustrates a cross-sectional surface of a structure illustrated in FIG. 60 taken along line A5-A5′ and viewed along an arrow direction. FIG. 62 illustrates a cross-sectional surface of a structure illustrated in FIG. 60 taken along line B5-B5′ and viewed along an arrow direction. In the following description, a similar reference numeral is given to a part similar to the third embodiment, and the description thereof is omitted.

The semiconductor memory device according to the fifth embodiment is configured basically similarly to the semiconductor memory device according to third embodiment. However, the semiconductor memory device according to the fifth embodiment includes contacts GBLC5 instead of the contacts GBLC3.

The contact GBLC5 is configured basically similarly to the contact GBLC3.

However, as illustrated in FIG. 60, the contacts GBLC5 are disposed inside the electrode structure 130c in the transistor layer TL. As illustrated in FIG. 61 and FIG. 62, the contact GBLC5 is disposed such that the contact GBLC5 passes through the electrode structure 130c disposed in the transistor layer TL2 and a surface SU45 as a lower surface of the contact GBLC5 is connected to the conductive layer 133c included in the electrode structure 130c disposed in the transistor layer TL1.

In the transistor layer TL2, the contact GBLC5 has both side surfaces in the X-direction and the Y-direction connected to the conductive layer 133c of the electrode structure 130c included in the transistor layer TL2. In the transistor layer TL1, the contact GBLC5 is connected to the conductive layer 133c of the electrode structure 130c included in the transistor layer TL1 from a Z-direction positive side.

### Another Embodiment

The semiconductor memory devices according to the first embodiment to the fifth embodiment are described above. However, the semiconductor memory devices according to these embodiments are merely examples, and a specific configuration or the like is appropriately adjustable.

For example, in the semiconductor memory device according to the first embodiment to the fifth embodiment, the two transistor layers TL arranged in the Z-direction are exemplified. However, the three or more transistor layers TL may be arranged in the Z-direction. The three or more transistors TrB disposed in these three or more transistor layers TL may be connected in parallel between the via-wiring 104(BL) and the global bit line GBL.

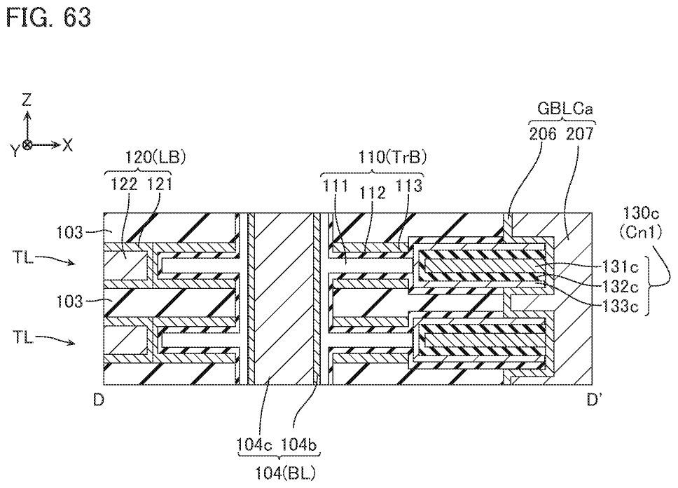

For example, in the semiconductor memory devices according to the first embodiment to the third embodiment, both side surfaces in the X-direction of the contacts GBLC, GBLC2 and the side surface on one side in the X-direction of the contact GBLC3 may partially have a shape as illustrated in FIG. 63 as the contact GBLCa. FIG. 63 is a schematic cross-sectional view illustrating a configuration of a part of a semiconductor memory device according to another embodiment.

A side surface on one side in the X-direction (a side surface in the X-direction negative side) of the contact GBLCa is disposed so as to enter the electrode structure 130c side. The contact GBLCa is in contact with not only the side surfaces in the X-direction of the conductive layers 133c included in the respective plurality of electrode structures 130c but also a part of upper surfaces and lower surfaces of the conductive layers 133c.

Note that, similarly, in the semiconductor memory device according to the fourth embodiment, the contact GBLC4 may be disposed such that a side surface on one side in the Y-direction enters the electrode structure 130c side and is in contact with a part of the upper surface and the lower surface of the electrode structure 130c.

Note that in the manufacturing method of the contact GBLCa, in the process described with reference to FIG. 48 and FIG. 49, when the insulating layers 107, 106, 103 are partially removed, the insulating layer 103 positioned between layers corresponding to the transistor layer TL is partially removed at the same time, and next, in the process described with reference to FIG. 50 and FIG. 51, the barrier conductive film 206 and the conductive film 207 are formed.

In the above description, as the memory portion connected to the transistor structure 110, an example of employing the capacitor CPC is described. However, the memory portion need not be the capacitor CPC. For example, the memory portion may be one that includes ferroelectric material, ferromagnet material, and chalcogen material such as GeSbTe or another material, and that stores data using characteristics of these materials. For example, in any of the structures described above, any of these materials may be contained in the insulating layer between the electrodes forming the capacitor CPC.

The manufacturing methods of the semiconductor memory devices according to the first embodiment to the fifth embodiment are appropriately adjustable. For example, two orders of any of the processes described above may be interchanged or any of the two processes described above may be simultaneously performed.

### Others

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A semiconductor memory device comprising:
a substrate;
a first wiring disposed on one side in a first direction intersecting with a surface of the substrate with respect to the substrate and extending in a second direction intersecting with the first direction;
a first semiconductor layer disposed between the substrate and the first wiring;
a plurality of second semiconductor layers disposed between the first semiconductor layer and the first wiring and stacked in the first direction;
a first via-wiring extending in the first direction and electrically connected to the first semiconductor layer and the plurality of second semiconductor layers;
a first memory portion electrically connected to the first semiconductor layer;
a first gate electrode opposed to the first semiconductor layer;
a second wiring extending in a third direction intersecting with the first direction and the second direction and electrically connected to the first gate electrode;
a plurality of connection electrodes disposed between the first memory portion and the first wiring, stacked in the first direction, and electrically connected to the respective plurality of second semiconductor layers;
a plurality of second gate electrodes disposed between the first gate electrode and the first wiring, stacked in the first direction, and opposed to the respective plurality of second semiconductor layers;
a plurality of third wirings disposed between the second wiring and the first wiring, stacked in the first direction, extending in the third direction, and electrically connected to the respective plurality of second gate electrodes;
a fourth wiring extending in the first direction and electrically connected to the first memory portion;
a fifth wiring extending in the first direction and electrically connected to the plurality of connection electrodes in common; and
an insulating layer disposed between the fourth wiring and the fifth wiring.

2. The semiconductor memory device according to claim 1, wherein
the plurality of connection electrodes include a first connection electrode closest to the first memory portion,
the fourth wiring has a first surface on a side close to the first wiring in the first direction,
the first surface is closer to the first wiring than a surface on a side of the first connection electrode of the first memory portion, and
the first surface is farther from the first wiring than a surface on a side of the first memory portion of the first connection electrode.

3. The semiconductor memory device according to claim 1, wherein
the first via-wiring has a second surface on a side close to the first wiring in the first direction,
the fifth wiring has a third surface on a side close to the first wiring in the first direction, and
the third surface is closer to the first wiring than the second surface.

4. The semiconductor memory device according to claim 3, wherein
the third surface is in contact with the first wiring.

5. The semiconductor memory device according to claim 1, wherein
the fifth wiring is electrically connected to the first wiring.

6. The semiconductor memory device according to claim 2, wherein
the fifth wiring has a fourth surface on a side far from the first wiring in the first direction,
the fourth surface is closer to the first wiring than a surface on a side of the first connection electrode of the first memory portion, and
the fourth surface is farther from the first wiring than a surface on an opposite side of the first memory portion of the first connection electrode.

7. The semiconductor memory device according to claim 2, comprising
a second memory portion disposed on a side in the first direction of the substrate with respect to the first memory portion;
a second connection electrode which is second closest to the first memory portion, the second connection electrode is one of the plurality of connection electrodes;
a first insulating layer disposed between the first memory portion and the second memory portion;
a second insulating layer disposed between the first connection electrode and the second connection electrode; and
a third insulating layer disposed between the first memory portion and the first connection electrode, wherein
the third insulating layer has a thickness in the first direction larger than a thickness of the first insulating layer in the first direction, and
the third insulating layer has the thickness in the first direction larger than a thickness of the second insulating layer in the first direction.

8. The semiconductor memory device according to claim 1, wherein
the fifth wiring is disposed between the fourth wiring and the first wiring.

9. The semiconductor memory device according to claim 1, comprising:
a third semiconductor layer disposed spaced from the first semiconductor layer in the second direction;
a plurality of fourth semiconductor layers spaced from the plurality of second semiconductor layers in the second direction and stacked in the first direction;
a second via-wiring extending in the first direction and electrically connected to the plurality of third semiconductor layers and the plurality of fourth semiconductor layers;
a fourth memory portion electrically connected to the third semiconductor layer; and
a plurality of third connection electrodes disposed between the fourth memory portion and the first wiring, stacked in the first direction, and electrically connected to the respective plurality of fourth semiconductors, wherein
the fifth wiring is electrically connected to the plurality of third connection electrodes in common.

10. The semiconductor memory device according to claim 1, wherein
the fifth wiring is disposed between the first memory portion and the first wiring.

11. The semiconductor memory device according to claim 1, wherein
each of the first semiconductor layer and the plurality of second semiconductor layers contains at least one element of gallium (Ga) and aluminum (Al), and contains indium (In), zinc (Zn), and oxygen (O).

12. The semiconductor memory device according to claim 1, wherein
the first memory portion is a capacitor.

13. The semiconductor memory device according to claim 1, wherein
the first gate electrode is opposed to one or both of a surface on one side and a surface on the other side in the first direction of the first semiconductor layer,
the first memory portion is disposed on one side in the second direction of the first semiconductor layer, and
the second wiring is disposed on the other side in the second direction of the first semiconductor layer.

14. The semiconductor memory device according to claim 1, wherein
the first semiconductor layer includes a first part and a second part, and
the first part extends in the first direction, and the second part extends in the second direction and is opposed to the first gate electrode in the first direction.

15. The semiconductor memory device according to claim 1, wherein
the plurality of second semiconductor layers each include a third part and a fourth part, and
the third part extends in the first direction, and the fourth part extends in the second direction and is opposed to the respective plurality of second gate electrodes in the first direction.

16. The semiconductor memory device according to claim 1, comprising
a first chip and a second chip bonded via a plurality of bonding electrodes, wherein
the first chip includes:
a plurality of the first semiconductor layers;
a plurality of the first wirings;
the plurality of second semiconductor layers;
a plurality of the first via-wirings;
a plurality of the first memory portions;
a plurality of the first gate electrodes;
a plurality of the second wirings;
the plurality of connection electrodes;
the plurality of second gate electrodes;
the plurality of third wirings;
the fourth wiring; and
a plurality of the fifth wirings, and
the second chip includes a control circuit electrically connected to a plurality of the first wirings.

17. A manufacturing method of the semiconductor memory device according to claim 1, comprising:
forming a first opening at a position corresponding to the fourth wiring;
forming a second opening at a position corresponding to the first memory portion via the first opening;
forming one electrode of the first memory portion inside the second opening;
forming an insulating film that covers the one electrode of the first memory portion inside the second opening, inside the first opening and the second opening;
forming a conductive layer that covers the insulating film inside the first opening and the second opening;
removing a part of the conductive layer to form the other electrode of the first memory portion and the plurality of connection electrodes;
forming the first via-wiring; and
forming the fifth wiring.

18. A semiconductor memory device comprising:
a plurality of first semiconductor layers stacked in a first direction;
a first wiring disposed on one side in the first direction of the plurality of first semiconductor layers, the first wiring extending in a second direction intersecting with the first direction;
a plurality of second semiconductor layers disposed between the plurality of first semiconductor layers and the first wiring and stacked in the first direction;
a first via-wiring extending in the first direction and electrically connected to the plurality of first semiconductor layers and the plurality of second semiconductor layers;
a plurality of first memory portions stacked in the first direction and electrically connected to the respective plurality of first semiconductor layers;
a plurality of first gate electrodes stacked in the first direction and opposed to the respective plurality of first semiconductor layers;
a plurality of second wirings stacked in the first direction, extending in a third direction intersecting with the first direction and the second direction, and electrically connected to the respective plurality of first gate electrodes;
a plurality of connection electrodes disposed between the plurality of first memory portions and the first wiring, stacked in the first direction, and electrically connected to the respective plurality of second semiconductor layers;
a plurality of second gate electrodes disposed between the plurality of first gate electrodes and the first wiring, stacked in the first direction, and opposed to the respective plurality of second semiconductor layers;
a plurality of third wirings disposed between the plurality of second wirings and the first wiring, stacked in the first direction, extending in the third direction, and electrically connected to the respective plurality of second gate electrodes;
a fourth wiring extending in the first direction and electrically connected to the plurality of first memory portions in common; and
a fifth wiring extending in the first direction and electrically connected to the plurality of connection electrodes in common.

19. The semiconductor memory device according to claim 18, wherein
the plurality of connection electrodes include a first connection electrode closest to the plurality of first memory portions,
the fourth wiring has a first surface on a side close to the first wiring in the first direction,
the first surface is closer to the first wiring than a surface on a side of the one first connection electrode closest to the plurality of connection electrodes among the plurality of first memory portions, and
the first surface is farther from the first wiring than a surface on a side of the plurality of first memory portions of the first connection electrode.

20. The semiconductor memory device according to claim 18, wherein
the first via-wiring has a second surface on a side close to the first wiring in the first direction,
the fifth wiring has a third surface on a side close to the first wiring in the first direction, and
the third surface is closer to the first wiring than the second surface.
